(19) United States
(12) Patent Application Publication
(10) Pub. No.: US 2018/0094361 A1
(43) Pub. Date: Apr. 5, 2018

(54) METHOD FOR PRODUCING GROUP III NITRIDE CRYSTAL, SEMICONDUCTOR APPARATUS, AND APPARATUS FOR PRODUCING GROUP III NITRIDE CRYSTAL

(71) Applicants: OSAKA UNIVERSITY, Suita-shi (JP); ITOCHU PLASTICS INC., Tokyo (JP)

(72) Inventors: Yusuke MORI, Osaka (JP); Masashi YOSHIMURA, Osaka (JP); Mamoru IMADE, Osaka (JP); Masayuki IMANISHI, Osaka (JP); Akira KITAMOTO, Osaka (JP); Masashi ISEMURA, Tokyo (JP)

(21) Appl. No.: 15/724,909

(22) Filed: Oct. 4, 2017

(30) Foreign Application Priority Data
Oct. 4, 2016 (JP) 2016-196509

(51) Int. Cl. C30B 29/40; C30B 25/18; H01L 21/02

(52) U.S. Cl. CPC C30B 29/403; H01L 21/02389; C30B 25/18

(57) ABSTRACT

The present invention provides a method for producing a Group III nitride crystal that can produce a Group III nitride crystal of high quality with few defects such as crack, dislocation, and the like by vapor phase epitaxy. In order to achieve the above object, the method for producing a Group III nitride crystal of the present invention includes a step of: causing Group III element-containing gas 111a to react with nitrogen-containing gas 203a and 203b to generate a Group III nitride crystal 204, wherein in the Group III nitride crystal generation step, the reaction is performed in the presence of a carbon-containing substance.

### TECHNICAL FIELD

The present invention relates to a method for producing a Group III nitride crystal, a semiconductor apparatus, and an apparatus for producing a Group III nitride crystal.

### BACKGROUND ART

A Group III nitride semiconductor (also called a Group III nitride compound semiconductor or a GaN semiconductor) such as gallium nitride (GaN) is used widely as materials for various semiconductor devices such as a laser diode (LD) and a light-emitting diode (LED). For example, the laser diode (LD) that emits blue light is applied to a high-density optical disc or a display, and a light-emitting diode (LED) that emits blue light is applied to a display or illumination. Moreover, an ultraviolet LD is expected to be applied to biotechnology and the like, and an ultraviolet LED is expected as an ultraviolet source of a fluorescent lamp.

As a common method for producing a Group III nitride (e.g., GaN) crystal substrate, there is vapor phase epitaxy such as hydride vapor phase epitaxy (HVPE) (Patent Document 1) and metalorganic chemical vapor deposition (MOCVD), for example. On the other hand, as a method that can produce a Group III nitride single crystal of higher quality, there is also liquid phase epitaxy. This liquid phase epitaxy had a problem in that the method was required to be performed under high temperature and high pressure. However, with recent improvements, the method can be performed under relatively low temperature and relatively low pressure and is suitable for mass production (for example, Patent Documents 2 and 3). Furthermore, there is a method that uses liquid phase epitaxy and vapor phase epitaxy in combination (Patent Document 4).

### CITATION LIST

### Patent Document(s)

Patent Document 1: S52(1977)-023600 A
Patent Document 2: JP 2002-293696 A
Patent Document 3: Japanese Patent No. 4588340
Patent Document 4: JP 2012-006772 A

### BRIEF SUMMARY OF THE INVENTION

### Problem to be Solved by the Invention

With recent increase in size and performance of semiconductor apparatuses, there is a demand for producing a Group III nitride crystal of high quality with few defects (e.g., crack, dislocation, etc.).

The liquid phase epitaxy allows a Group III nitride crystal with few defects to be produced easily, however, it requires a long period of time for crystal growth.

On the other hand, the vapor phase epitaxy achieves a high crystal growth speed, however, it is difficult to produce a Group III nitride crystal of high quality with few defects.

Hence, the present invention is intended to provide a method for producing a Group III nitride crystal that produces a Group III nitride crystal of high quality with few defects by vapor phase epitaxy. Furthermore, the present invention provides a semiconductor apparatus produced by the method for producing a Group III nitride crystal and an apparatus for producing a Group III nitride crystal for use in the method for producing a Group III nitride crystal.

### Means for Solving Problem

In order to achieve the above object, the present invention provides a method for producing a Group III nitride crystal (hereinafter, it may be simply referred to as the “production method according to the present invention”), including a step of: causing Group III element-containing gas to react with nitrogen-containing gas to generate a Group III nitride crystal, wherein in the Group III nitride crystal generation step, the reaction is performed in the presence of a carbon-containing substance.

The present invention also provides a method for producing a semiconductor apparatus including a Group III nitride crystal, including a step of: producing a Group III nitride crystal by the production method according to the present invention, wherein the Group III nitride crystal is a semiconductor.

The present invention also provides an apparatus for producing a Group III nitride crystal for use in the production method according to the present invention, including: a Group III nitride crystal generation unit configured to perform the Group III nitride crystal generation step.

### Effects of the Invention

According to the production method of the present invention, a Group III nitride crystal of high quality with few defects can be produced by vapor phase epitaxy. Furthermore, the present invention provides a semiconductor apparatus that can be produced by the production method according to the present invention and a Group III nitride crystal production apparatus that can be used in the production method according to the present invention.

### BRIEF DESCRIPTION OF DRAWINGS

FIG. 1 is a cross sectional view schematically showing an example of an apparatus for use in the method for producing a Group III nitride crystal of the present invention.

FIG. 2 is a cross sectional view schematically showing an example of the method for producing a Group III nitride crystal using the apparatus shown in FIG. 1.

FIG. 3 is a cross sectional view schematically showing another example of the method for producing a Group III nitride crystal using the apparatus shown in FIG. 1.

FIG. 4 is a cross sectional view schematically showing another example of an apparatus for use in the method for producing a Group III nitride crystal of the present invention.

FIG. 5 is a cross sectional view schematically showing an example of the method for producing a Group III nitride crystal using the apparatus shown in FIG. 4.

FIG. 6 is a cross sectional view schematically showing still another example of an apparatus for use in the method for producing a Group III nitride crystal of the present invention.

FIG. 7 is a cross sectional view schematically showing an example of the method for producing a Group III nitride crystal using the apparatus shown in FIG. 6.

FIG. 8 is a table showing the XRC half width, dislocation density, and crack density in the case of producing a GaN crystal by providing solid carbon (graphite) in the apparatus in Example.

FIG. 9 is an illustration schematically showing a method of calculating the crack density.

FIG. 10 is a graph showing the relationship between the carbon supply amount (decrease amount) and the XRC half width and dislocation density of the GaN crystal in Example of FIG. 8.

FIG. 11 is a table showing the relationship between the methane flow rate and the XRC half width, crack rate, and dislocation density in the case of producing a GaN crystal using methane gas in Example.

FIG. 12 is a graph showing the relationship between the methane flow rate and the crack rate of the GaN crystal in Example of FIG. 11.

FIG. 13 is a graph showing the relationship between the methane flow rate and the XRC half width of the GaN crystal in Example of FIG. 11.

FIG. 14 is a table showing the XRC half width, crack rate, and dislocation density in the case of producing a GaN crystal using metal gallium, H₂O gas, and methane gas in Example.

### MODE FOR CARRYING OUT THE INVENTION

The present invention is described below with reference to examples. The present invention, however, is not limited by the following description.

In the method for producing a Group III nitride crystal of the present invention, for example, the carbon-containing substance may be at least one selected from the group consisting of elementary carbon, solid elementary carbon, graphite, carbon nanotube, fullerene, a carbon compound, a solid carbon compound, carbon-containing gas, carbon monoxide (CO) gas, and hydrocarbon gas.

In the method for producing a Group III nitride crystal of the present invention, the nitrogen-containing gas may be at least one selected from the group consisting of N₂, NH₃, hydrazine gas, and alkylamine gas, for example.

The method for producing a Group III nitride crystal of the present invention may further include a step of generating the Group III element-containing gas, for example. The Group III element-containing gas generation step may be a step of causing Group III element metal to react with an oxidizing agent to generate the Group III element-containing gas, for example. Hereinafter, such a method for producing a Group III nitride crystal of the present invention may also be referred to as a “Group III nitride crystal production method (A)”. In the Group III nitride crystal production method (A), the Group III element-containing gas generated in the Group III element-containing gas generation step is, for example, gas produced by oxidation of Group III element metal (hereinafter, also referred to as Group III element metal oxidation product gas). Hereinafter, the Group III element-containing gas generation step of causing Group III element metal to react with an oxidizing agent to generate Group III element metal oxidation product gas (Group III element-containing gas) may also be referred to as a “Group III element metal oxidation product gas generation step”.

As described above, the method for producing a Group III nitride crystal of the present invention may further include a step of generating the Group III element-containing gas. The Group III element-containing gas generation step may be a step of causing Group III element oxide to react with reducing gas to generate the Group III element-containing gas, for example. Hereinafter, such a method for producing a Group III nitride crystal of the present invention may also be referred to as a “Group III nitride crystal production method (B)”. In the Group III nitride crystal production method (B), the Group III element-containing gas generated in the Group III element-containing gas generation step is, for example, reduced product gas of the Group III element oxide. Hereinafter, the Group III element-containing gas generation step of causing Group III element oxide to react with reducing gas to generate reduced product gas of Group III element oxide (Group III element-containing gas) may also be referred to as “a reduced product gas generation step”.

In the Group III nitride crystal production method (A) in the production method according to the present invention, the Group III element metal is preferably at least one selected from the group consisting of gallium, indium and aluminum, and is particularly preferably gallium.

In the Group III element metal oxidation product gas generation step, preferably, the Group III element metal is caused to react with the oxidizing agent in a heated state. Furthermore, more preferably, the Group III element metal oxidation product gas is Group III element metal oxide gas. In this case, still more preferably, the Group III element metal is gallium and the Group III element metal oxide gas is Ga₂O gas.

In the Group III nitride crystal production method (A), preferably, the oxidizing agent is an oxygen-containing compound. Also, in the Group III nitride crystal production method (A), preferably, the oxidizing agent is oxidizing gas.

In the Group III nitride crystal production method (A), the oxidizing gas is preferably at least one selected from the group consisting of H₂O gas, O₂ gas, CO₂ gas, and CO gas, and is particularly preferably H₂O gas.

In the Group III nitride crystal production method (A), the nitrogen-containing gas is preferably at least one selected from the group consisting of N₂, NH₃, hydrazine gas, and alkylamine gas.

In the method for producing a Group III nitride crystal, the volume of the oxidizing gas is not particularly limited, and the volume relative to the total volume of the oxidizing gas and the nitrogen-containing gas is, for example, more than 0% and less than 100%, preferably 0.001% or more and less than 100%, and more preferably in the range from 0.01% to 95%, still more preferably in the range from 0.1% to 80%, and still more preferably in the range from 0.1% to 60%.

In the Group III nitride crystal production method (A), preferably, the reaction takes place in the presence of reducing gas in a reaction system. More preferably, the reducing gas is hydrogen-containing gas. Still more preferably, the reducing gas is at least one selected from the group consisting of H₂ gas, carbon monoxide (CO) gas, hydrocarbon gas, H₂S gas, SO₂ gas, and NH₃ gas. In the method for producing a Group III nitride crystal, still more preferably, the oxidizing agent is the oxidizing gas and the reaction is performed after being mixed with the reducing gas in the oxidizing gas.

In the method for producing a Group III nitride crystal, more preferably, the reaction in the presence of the reducing gas is performed at a temperature of 650° C. or higher.

In the Group III nitride crystal production method (A), the Group III nitride crystal may be generated in a condition under pressure, in a condition under reduced pressure, or in conditions other than these conditions.

In the reduced product gas generation step of the Group III nitride crystal production method (B) according to the present invention, preferably, the Group III element oxide is caused to react with the reducing gas in a heated state.

In the Group III nitride crystal production method (B), preferably, the Group III element oxide is Ga₂O₃, the reduced product gas is Ga₂O gas, and the Group III nitride crystal is a GaN crystal.

In the Group III nitride crystal production method (B), preferably, the reduced product gas generation step is performed in an atmosphere of mixed gas of the reducing gas and inert gas. More preferably, the proportion of the reducing gas relative to the total amount of the mixed gas is 0.1 vol. % or more and less than 100 vol. % and the proportion of the inert gas relative to the total amount of the mixed gas is more than 0 vol. % and 99.9 vol. % or less. Still more preferably, the inert gas contains nitrogen gas.

In the Group III nitride crystal production method (B), preferably, the nitrogen-containing gas contains ammonia gas.

The crystal generation step of the Group III nitride crystal production method (B) may be performed, for example, in a condition under pressure. The present invention, however, is not limited thereto and the crystal generation step may be performed in a condition under reduced pressure or in conditions other than these conditions.

Preferably, the production method according to the present invention further includes a slicing step of slicing the Group III nitride crystal to provide at least one Group III nitride crystal substrate.

Furthermore, preferably, the production method according to the present invention further includes a step of polishing the surface of the substrate. In the method for producing a Group III nitride crystal, preferably, the Group III nitride crystal is produced by vapor phase epitaxy on the surface of the substrate polished in the polishing step.

In the production method according to the present invention, the Group III nitride crystal is preferably a Group III nitride crystal represented by AlₓGa_{y}In_{1-x-y}N (0≦x≦1, 0≦y≦1, x+y≦1) and particularly preferably GaN.

In the production method according to the present invention, preferably, the produced Group III nitride crystal has a major axis of 15 cm or more, although it is not particularly limited. Furthermore, preferably, the produced Group III nitride crystal has a dislocation density of 1.0×10⁷ cm⁻² or less, although it is not particularly limited. Moreover, in the produced Group III nitride crystal, preferably, a half width of each of a symmetric reflection component (002) and an asymmetric reflection component (102) by an X-ray rocking curve method (XRC) is 300 seconds or less, although it is not particularly limited. The concentration of the oxygen contained in the Group III nitride crystal produced may be 1×10²⁰ cm⁻³ or less. The present invention, however, is not limited thereto and the concentration of the oxygen contained in the produced Group III nitride crystal may be more than 1×10²⁰ cm⁻³. The method for measuring the half width and the dislocation density by the XRC is not limited to particular methods, and the methods described in Examples below can be adopted.

More specifically, the production method according to the present invention can be performed, for example, as follows.

### 1. Group III Nitride Seed Crystal

First, prior to the Group III nitride crystal generation step, a substrate for crystal growth is prepared. On the surface of the substrate, a Group III nitride crystal can be generated and grown.

The substrate is not limited to particular substrates and may be, for example, the same as or similar to a substrate for use in common vapor phase epitaxy. The substrate can be selected appropriately according to the form or the like of a Group III nitride crystal to be generated thereon. Examples of the material for the substrate include sapphire, Group III nitride (e.g., AlₓGa₁₋ₓN (0<x≦1)), gallium arsenide (GaAs), silicon (Si), silicon carbide (SiC), magnesium oxide (MgO), zinc oxide (ZnO), gallium phosphide (GaP), zirconium diboride (ZrB₂), lithium dioxogallate (LiGaO₂), BP, MoS₂, LaAlO₃, NbN, MnFe₂O₄, ZnFe₂O₄, ZrN, TiN, MgAl₂O₄, NdGaO₃, LiAlO₂, ScAlMgO₄, and Ca₈La₂(PO₄)₆O₂. Among them, sapphire is particularly preferable from the viewpoint of costs and the like. In the present invention, “sapphire” denotes an aluminum oxide crystal or a crystal containing aluminum oxide as a main component, unless otherwise stated.

The substrate may include an underlayer (substrate body) and a seed crystal disposed thereon. The form of the seed crystal is not limited to particular forms, and the seed crystal can be in the shape of a layer, a needle, a feather, or a plate, for example. The material for the underlayer (substrate body) is not limited to particular materials, and can be, for example, as described above. The material for the seed crystal is not limited to particular materials, and examples thereof include Group III nitride (e.g., AlₓGa₁₋ₓN (0<x≦1)), oxide of the AlₓGa₁₋ₓN (0<x≦1), diamond-like carbon, silicon nitride, silicon oxide, silicon oxynitride, aluminum oxide, aluminum oxynitride, silicon carbide, yttrium oxide, yttrium aluminum garnet (YAG), tantalum, rhenium, and tungsten.

The material for the substrate or the seed crystal may be, for example, the same as or different from the material for the Group III nitride crystal of the present invention to be grown thereon, and is preferably the same as the material for the Group III nitride crystal of the present invention to be grown thereon. For example, a sapphire substrate and a Group III nitride crystal are largely different in the lattice constant, the thermal expansion coefficient, and the like. Thus, when a Group III nitride crystal is directly grown on a sapphire substrate by vapor phase epitaxy, defects such as a distortion, a dislocation, warping, and the like may be caused in the Group III nitride crystal. In this regard, when a substrate of the same material as a Group III nitride crystal (e.g., GaN or the like) to be produced is used or a seed crystal having the same material as a Group III nitride crystal (e.g., GaN or the like) to be produced is formed on the substrate (e.g., sapphire or the like), the defects such as a distortion, a dislocation, warping, and the like can be inhibited or prevented. For example, by forming a crystal on an underlayer (substrate body) using the above-described material for seed crystal, the seed crystal can be disposed on the underlayer. Examples of such a method include the metalorganic vapor phase epitaxy (MOVPE method), the molecular beam epitaxy (MBE method), the halide vapor phase epitaxy (HVPE method), and the liquid phase epitaxy (LPE method). Among them, the liquid phase epitaxy is preferable from the viewpoint of obtaining a seed crystal of few defects such as a dislocation and the like. The liquid phase epitaxy can be, for example, a sodium flux method.

An apparatus (LPE apparatus) for use in the liquid phase epitaxy is not limited to particular apparatuses and may be the same as a common LPE apparatus, for example. Specifically, for example, the apparatus may be an LPE apparatus or the like described in Patent Document 3 (Japanese Patent No. 4588340).

### 2. Group III Element-Containing Gas Generation Step and Group III Nitride Crystal Generation Step

Next, the Group III nitride crystal generation step of causing Group III element-containing gas to react with nitrogen-containing gas to generate a Group III nitride crystal is performed. According to the present invention, as described above, in the Group III nitride crystal generation step, the reaction is performed in the presence of a carbon-containing substance.

As described above, the method for producing a Group III nitride crystal of the present invention may include a Group III element-containing gas generation step of generating the Group III element-containing gas prior to the Group III nitride crystal generation step as described above.

In the method for producing a Group III nitride crystal of the present invention, as described above, the Group III element-containing gas generation step may be a step of causing Group III element metal to react with an oxidizing agent to generate the Group III element-containing gas (Group III nitride crystal production method (A)). Also, in the method for producing a Group III nitride crystal of the present invention, as described above, the Group III element-containing gas generation step may be a step of causing Group III element oxide to react with reducing gas to generate the Group III element-containing gas (Group III nitride crystal production method (B)). The Group III nitride crystal production methods (A) and (B) can be performed as described below, for example.

### 2-1. Production Apparatus of Group III Nitride Crystal

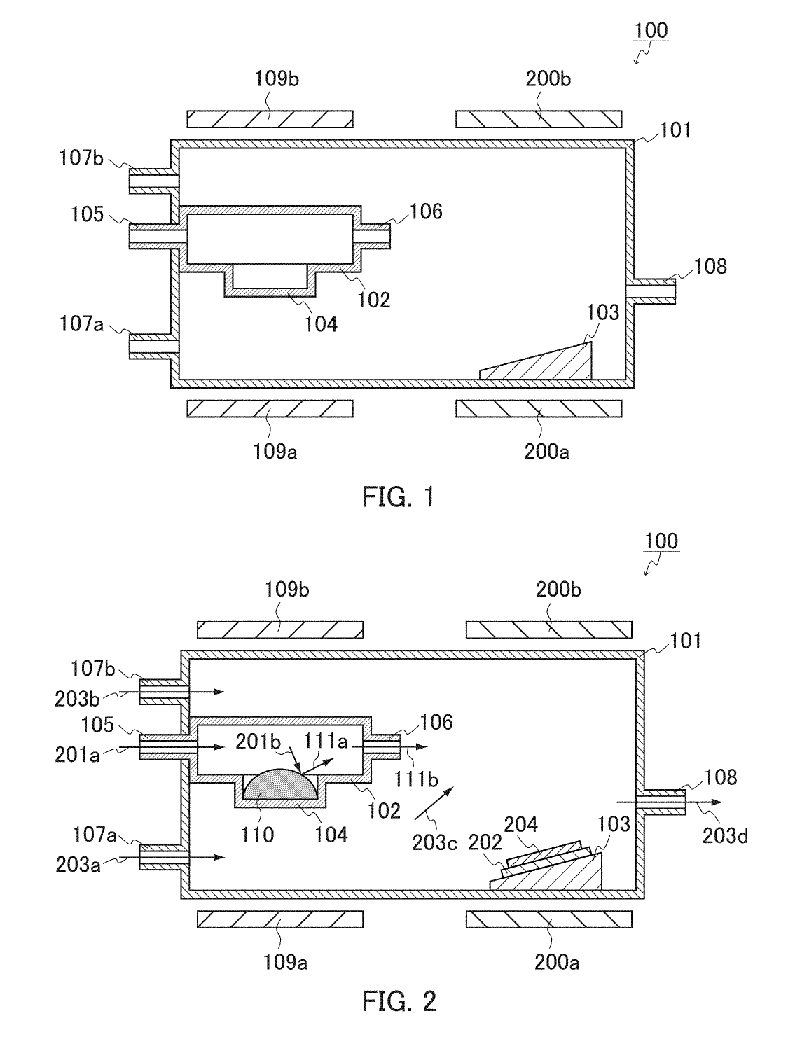

FIG. 1 shows an example of the configuration of the production apparatus (production apparatus of a Group III nitride crystal of the present invention) for use in the Group III nitride crystal production method (A). FIG. 1 is a schematic view, and the size, the ratio, and the like of the components of an actual apparatus are not limited to the configuration shown in FIG. 1. As shown in FIG. 1, a production apparatus 100 of the present Example includes a first container 101, a second container 102, and a substrate support 103, and the second container 102 and the substrate support 103 are disposed in the first container 101. The second container 102 is fixed at the left side surface of the first container 101 in FIG. 1. The substrate support 103 is fixed at the lower surface of the first container 101. The second container 102 includes a Group III element metal placement part 104 at its lower surface. The second container 102 is provided with an oxidizing gas introduction pipe 105 at its left side surface and is provided with a Group III element metal oxidation product gas delivery pipe 106 at its right side surface in FIG. 1. Oxidizing gas can be continuously introduced (supplied) into the second container 102 through the oxidizing gas introduction pipe 105. The first container 101 is provided with nitrogen-containing gas introduction pipes 107a and 107b at its left side surface and is provided with an exhaust pipe 108 at its right side surface in FIG. 1. Nitrogen-containing gas can be continuously introduced (supplied) into the first container 101 through the nitrogen-containing gas introduction pipes 107a and 107b. Furthermore, at the outside of the first container 101, first heating units 109a and 109b and second heating units 200a and 200b are disposed. However, the production apparatus for use in the production method of the present invention is not limited to this example. For example, although the number of second containers 102 disposed in the first container 101 in this example is one, the number of second containers 102 disposed in the first container 101 may be more than one. Furthermore, although the number of the oxidizing gas introduction pipes 105 is one in this example, the number of the oxidizing gas introduction pipes 105 may be more than one. While the production apparatus 100 shown in FIG. 1 is described as an apparatus for use in the Group III nitride crystal production method (A), as is described below, the production apparatus 100 shown in FIG. 1 can be used also in the Group III nitride crystal production method (B).

The shape of the first container is not limited to particular shapes. Examples of the shape of the first container include a cylinder, a quadratic prism, a triangular prism, and a shape created by combining these shapes. Examples of the material for forming the first container include quartz, alumina, aluminum titanate, mullite, tungsten, and molybdenum. A self-made first container or a commercially available first container may be used. The commercially available first container can be, for example, the “quartz reaction tube” (product name) produced by PHOENIX TECHNO.

The shape of the second container is not limited to particular shapes. Examples of the shape of the second container include those described for the first container. Examples of the material for forming the second container include quartz, tungsten, stainless, molybdenum, aluminum titanate, mullite, and alumina. A self-made second container or a commercially available second container may be used. The commercially available second container can be, for example, the “SUS316BA tube” (product name) produced by Mecc Technica Co.

Conventionally known heating units can be used as the first heating unit and the second heating unit. Examples of the heating unit include ceramic heaters, high frequency heaters, resistance heaters, and light collecting heaters. One type of the heating units may be used alone or two or more of them may be used in combination. Preferably, the first heating unit and the second heating unit are each independently controlled.

FIG. 4 shows another example of the configuration of the production apparatus for use in the Group III nitride crystal production method (A). As shown in FIG. 4, this production apparatus 300 has the same configuration as the production apparatus 100 shown in FIG. 1 except that it includes a second container 301 instead of a second container 102. As shown in FIG. 4, the second container 301 is provided with oxidizing gas introduction pipe 105 at the upper part of its left side surface, is provided with a Group III element metal introduction pipe 302 at the lower part of its left side surface, and is provided with a Group III element metal oxidation product gas delivery pipe 106 at its right side surface. Oxidizing gas can be continuously introduced (supplied) into the second container 301 through the oxidizing gas introduction pipe 105. Group III element metal can be continuously introduced (supplied) into the second container 301 through the Group III element metal introduction pipe 302. The second container 301 does not include a Group III element metal placement part 104, instead, it has a deep depth (vertical width) and allows a Group III element metal to be stored in its lower part. The first container 101 and the second container 301 of the production apparatus shown in FIG. 4 each can be referred to as a “reaction vessel”. The Group III element metal introduction pipe 302 corresponds to a “Group III element metal supply unit”. The oxidizing gas introduction pipe 105 can be referred to as an “oxidizing agent supply unit”. The nitrogen-containing gas introduction pipes 107a and 107b each can be referred to as a “nitrogen-containing gas supply unit”. In the present invention, the production apparatus (the Group III nitride crystal production apparatus using the vapor phase epitaxy) for use in the Group III nitride crystal production method may be, for example, as the apparatus shown in FIG. 4, an apparatus for producing a Group III nitride crystal in which the Group III element metal can be continuously supplied into the reaction vessel by the Group III element metal supply unit, the oxidizing agent can be continuously supplied into the reaction vessel by the oxidizing agent supply unit, the nitrogen-containing gas can be continuously supplied into the reaction vessel by the nitrogen-containing gas supply unit, and the Group III element metal, the oxidizing agent, and the nitrogen-containing gas are caused to react in the reaction vessel to produce a Group III nitride crystal.

FIG. 6 shows still another example of the configuration of the apparatus for use in the Group III nitride crystal production method (A). As shown in FIG. 6, this production apparatus 500 includes a carrier gas introduction pipe 107c and a nitrogen-containing gas introduction pipe 107d instead of nitrogen-containing gas introduction pipes 107a and 107b. The right side surface of the second container 102 does not include the Group III element metal oxidation product gas delivery pipe 106, instead, the whole right side surface opens so that the Group III element metal oxidation product gas can be delivered. The carrier gas introduction pipe 107c is provided around the second container 102 from the left end to the right end, and the nitrogen-containing gas introduction pipe 107d is provided around the carrier gas introduction pipe 107c from the left end to the right end. The substrate support 103 is attached in the vicinity of the end of the exhaust pipe 108 and is disposed such that the surface of the substrate 202 attached to the substrate support 103 faces the right side of the second container 102. Except for these, the production apparatus 500 shown in FIG. 6 is the same as the production apparatus 100 shown in FIG. 1.

The configuration of the production apparatus for use in the method for producing a Group III nitride crystal is not limited to those shown in FIGS. 1, 4, and 6. For example, the heating units 109a, 109b, 200a, and 200b and the substrate support 103 can be omitted. However, from the viewpoint of reactivity and operability, the production apparatus is preferably provided with these components. Furthermore, the production apparatus for use in the production method of the present invention may be provided with other components in addition to the above-described components. Examples of other components include a unit configured to control the temperatures of the first heating unit and the second heating unit and a unit configured to adjust the pressure and the introduction amount of the gas used in each step.

The production apparatus for use in the Group III nitride crystal production method (A) can be produced by assembling the above-described components and other components as needed according to a conventionally known method, for example.

### 2-2. Production Steps, Reaction Conditions, and the Like in Group III Nitride Crystal Production Method (A)

Next, steps, reaction conditions, materials to be used, and the like in the Group III nitride crystal production method (A) are described. The present invention, however, is not limited by the following description. A mode for carrying out the Group III nitride crystal production method (A) is described below with reference to the production apparatus shown in FIG. 1 or the production apparatus shown in FIG. 4 or 6 instead of the production apparatus shown in FIG. 1. The production apparatus shown in FIG. 1, 4, or 6 itself can also be referred as a “Group III nitride crystal generation unit” for performing the Group III nitride crystal generation step. As described below, since the Group III nitride crystal is generated on the substrate 202 provided on the substrate support 103, the substrate support 103 can also be referred to as a “Group III nitride crystal generation unit”.

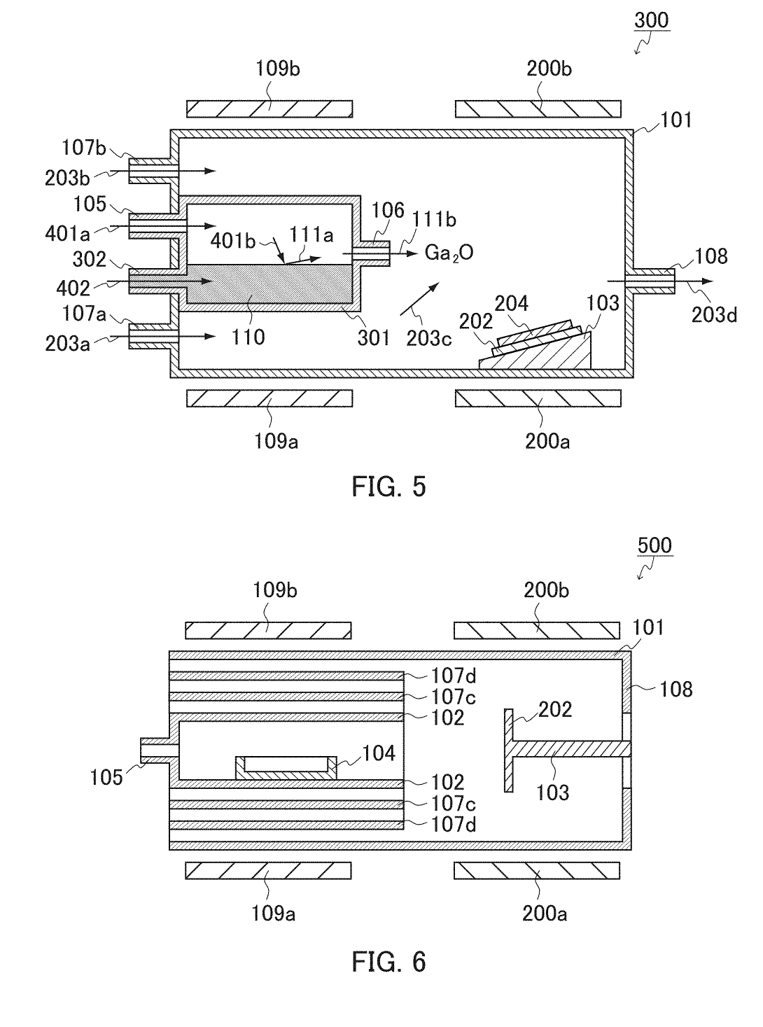

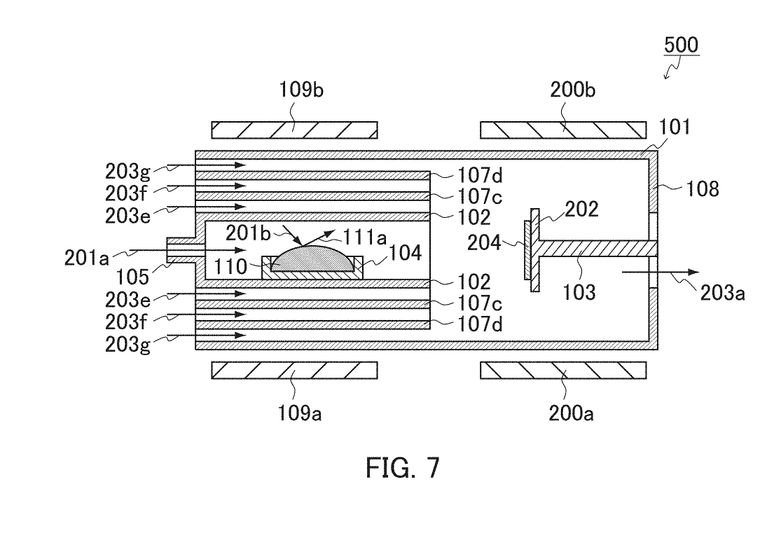

First, as shown in FIG. 2 (or FIG. 5 or 7), the substrate 202 is previously disposed on the substrate support 103. The substrate 202 is not limited to particular substrates and is, for example, as described above. The substrate 202 can be, for example, a sapphire substrate, a seed crystal formed of Group III nitride (e.g., GaN), or a seed crystal of Group III nitride formed on an underlayer (substrate body) formed of sapphire. The substrate 202 can be selected appropriately according to the form of the Group III nitride crystal to be generated thereon. The material for the substrate 202 main body or the seed crystal formed thereon may be, as described above, the same as or different from the material for the Group III nitride crystal to be grown thereon, and is preferably the same as the material for the Group III nitride crystal to be grown thereon.

Next, as shown in FIG. 2 (or FIG. 7), a Group III element metal 110 is disposed on a Group III element metal placement part 104. When the production apparatus shown in FIG. 4 is used, as shown in FIG. 5, a Group III element metal 402 is introduced into a second container 301 from a Group III element metal introduction pipe 302 and is stored in the lower part of the second container 301 as a Group III element metal 110. The Group III element metal 402 can be continuously introduced into the second container 301 from the Group III element metal introduction pipe 302. For example, the Group III element metal 402 can be introduced from the Group III element metal introduction pipe 302 to refill a quantity equivalent to the amount of the Group III element metal 402 consumed by reaction. The Group III element metal is not limited to a particular metal and examples thereof include aluminum (Al), gallium (Ga), indium (In), and thallium (Tl), and one of them may be used alone or two or more of them may be used in combination. For example, as the Group III element metal, at least one selected from the group consisting of aluminum (Al), gallium (Ga), and indium (In) may be used. In this case, the composition of the Group III nitride crystal to be produced can be represented by AlₛGaₜIn_{{1-(s+t)}}N (provided that, 0≦s≦1, 0≦t≦1, s+t≦1). Furthermore, the Group III element metal 110 may be caused to react in the presence of a dopant material or the like, for example. The dopant is not particularly limited, and examples thereof include germanium oxides (e.g., Ge₂O₃, Ge₂O, and the like).

Furthermore, a ternary or higher nitride crystal produced using two or more kinds of Group III element metals can be, for example, a crystal represented by GaₓIn₁₋ₓN (0<x<1). For generating a ternary or higher nitride crystal, it is preferable to generate reduced product gas of at least two kinds of Group III element oxides. In this case, it is preferable to use a production apparatus provided with at least two second containers.

Because of its relatively low melting point, a Group III element metal easily becomes liquid by heating. When the Group III element metal is liquid, it can be easily supplied into a reaction vessel (second container 301 in FIG. 5) continuously. Among the above-described Group III element metals, gallium (Ga) is particularly preferable. It is because gallium nitride (GaN) produced from gallium is very useful as a material for a semiconductor apparatus. In addition, since gallium can become liquid near room temperature because of its low melting point (about 30° C.), it can be particularly easily supplied to a reaction vessel continuously. When only gallium is used as the Group III element metal, a Group III nitride crystal to be produced is gallium nitride (GaN) as described above.

Next, the Group III element metal 110 is heated using first heating units 109a and 109b and the substrate 202 is heated using second heating units 200a and 200b. In this state, oxidizing gas 201a (or 401a) is introduced from oxidizing gas introduction pipe 105, and nitrogen-containing gas 203a and 203b is introduced from the nitrogen-containing gas introduction pipes 107a and 107b. When the apparatus shown in FIG. 6 (FIG. 7) is used, nitrogen-containing gas 203f is introduced from a nitrogen-containing gas introduction pipe 107d instead of the nitrogen-containing gas introduction pipes 107a and 107b, carrier gas 203e is introduced from the carrier gas introduction pipe 107c, and carrier gas 203g is introduced from the outer side of the nitrogen-containing gas introduction pipe 107d. The carrier gas 203e and 203g is, for example, nitrogen gas (N₂), and is described below in detail. The oxidizing gas 201a (or 401a) is not limited to particular gas. As described above, the oxidizing gas 201a (or 401a) is preferably at least one selected from the group consisting of H₂O gas, O₂ gas, CO₂ gas, and CO gas, and is particularly preferably H₂O gas. The oxidizing gas 201a (or 401a) introduced (supplied) into the second container 102 (or 301) comes into contact with the surface of the Group III element metal 110 (oxidizing gas 201b or 401b). The Group III element metal 110 is thereby caused to react with the oxidizing gas 201b (or 401b) to generate Group III element metal oxidation product gas (Group III element-containing gas) 111a (Group III element metal oxidation product gas generation step). The flow rate of the oxidizing gas is, for example, in the range from 0.0001 to 50 Pa·m³/s, preferably in the range from 0.001 to 10 Pa·m³/s, and more preferably in the range from 0.005 to 1 Pa·m³/s.

In the Group III element metal oxidation product gas generation step in the production method of the present invention, from the viewpoint of promoting the generation of the Group III element metal oxidation product gas, preferably, the Group III element metal is caused to react with the oxidizing gas in a heated state. In this case, the temperature of the Group III element oxide is not particularly limited, and is preferably in the range from 650° C. to 1500° C., more preferably in the range from 900° C. to 1300° C., and still more preferably in the range from 1000° C. to 1200° C.

In the Group III element metal oxidation product gas generation step, particularly preferably, the Group III element metal is gallium, the oxidizing gas is H₂O gas, and the Group III element metal oxidation product gas is Ga₂O. The reaction formula of this case can be represented by the following formula (I), for example. The reaction formula, however, is not limited thereto.

2Ga+H₂O→Ga₂O+H₂ (I)

In the production method of the present invention, from the viewpoint of controlling the partial pressure of the oxidizing gas, the Group III element metal oxidation product gas generation step may be performed in an atmosphere of mixed gas of the oxidizing gas and inert gas. There are no particular limitations on the proportions of the oxidizing gas and the inert gas relative to the total amount of the mixed gas. Preferably, the proportion of the oxidizing gas relative to the total amount of the mixed gas is 0.001 vol. % or more and less than 100 vol. % and the proportion of the inert gas relative to the total amount of the mixed gas is more than 0 vol. % and 99.999 vol. % or less. More preferably, the proportion of the oxidizing gas relative to the total amount of the mixed gas is 0.01 vol. % or more and 80 vol. % or less and the proportion of the inert gas relative to the total amount of the mixed gas is 20 vol. % or more and 99.99 vol. % or less. Still more preferably, the proportion of the oxidizing gas relative to the total amount of the mixed gas is 0.1 vol. % or more and 60 vol. % or less and the proportion of the inert gas relative to the total amount of the mixed gas is 40 vol. % or more and 99.9 vol. % or less. In the production method of the present invention, examples of the inert gas include nitrogen gas, helium gas, argon gas, and krypton gas. Among them, nitrogen gas is particularly preferable. Examples of the method for creating the mixed gas atmosphere include a method of introducing inert gas from an inert gas introduction pipe (not shown) provided in the second container separately from the oxidizing gas introduction pipe; and a method of preliminarily generating gas in which the hydrogen gas and the inert gas are mixed at predetermined proportions and introducing the thus obtained gas from the oxidizing gas introduction pipe. In the case of introducing the inert gas from the separately provided inert gas introduction pipe, the flow rate of the inert gas can be set appropriately according to the flow rate of the oxidizing gas and the like. The flow rate of the inert gas is, for example, in the range from 0.1 to 150 Pa·m³/s, preferably in the range from 0.2 to 30 Pa·m³/s, and more preferably in the range from 0.3 to 10 Pa·m³/s.

The generated Group III element metal oxidation product gas 111a is delivered to the outside of the second container 102 (or 301) through the Group III element metal oxidation product gas delivery pipe 106 (Group III element metal oxidation product gas 111b). Although the Group III element metal oxidation product gas 111b shown in FIG. 5 is Ga₂O, the Group III element metal oxidation product gas 111b is not limited thereto. For delivering the Group III element metal oxidation product gas 111b to the outside of the second container 102 (or 301) through the Group III element metal oxidation product gas delivery pipe 106, first carrier gas may be introduced. As the first carrier gas, for example, the examples described for the inert gas can be used. The flow rate (partial pressure) of the first carrier gas can be the same as that of the inert gas. In the case of introducing the inert gas, the inert gas can be used as the first carrier gas.

The generation of the Group III element metal oxidation product gas 111a (111b) may be performed in a condition under pressure, in a condition under reduced pressure, or in conditions other than these conditions, for example. The pressure in the condition under pressure is not particularly limited, and is preferably in the range from 1.0×10⁵ to 1.50×10⁷ Pa, more preferably in the range from 1.05×10⁵ to 5.00×10⁶ Pa, and more preferably in the range from 1.10×10⁵ to 9.90×10⁵ Pa. The method of applying pressure can be, for example, a method of applying pressure by the oxidizing gas, the first carrier gas, or the like. The pressure in the condition under reduced pressure is not particularly limited, and is preferably in the range from 1×10¹ to 1×10⁵ Pa, more preferably in the range from 1×10² to 9×10⁴ Pa, and still more preferably in the range from 5×10³ to 7×10⁴ Pa.

The Group III element metal oxidation product gas (e.g., Ga₂O gas) 111b delivered to the outside of the second container 102 (or 301) through the Group III element metal oxidation product gas delivery pipe 106 is caused to react with nitrogen-containing gas 203c introduced into the first container 101, and a Group III nitride (e.g., GaN) crystal 204 is generated on the substrate 202 (Group III nitride crystal generation step). The reaction formula of this case can be represented, for example, by the following formula (II) in the case where the Group III element metal oxidation product gas is Ga₂O gas and the nitrogen-containing gas is ammonia gas. The reaction formula, however, is not limited thereto. Note that excess remaining gas after reaction can be exhausted from the exhaust pipe 108 as exhaust gas 203d.

Ga₂O+2NH₃→2GaN+2H₂O+2H₂ (II)

In the production method of the present invention, examples of the nitrogen-containing gas include nitrogen gas (N₂), ammonia gas (NH₃), hydrazine gas (NH₂NH₂), and alkylamine gas (e.g., C₂H₈N₂). The nitrogen-containing gas is particularly preferably NH₃.

The present invention is, as described above, characterized in that the reaction is performed in the presence of a carbon-containing substance in the Group III nitride crystal generation step. The form of the carbon-containing substance is not particularly limited and may be, for example, solid, liquid, or gas at room temperature. In the case where the carbon-containing substance is gas at room temperature, for example, since the reaction can be performed while appropriately adjusting the introduction amount (flow rate) of the carbon-containing substance in the Group III nitride crystal production apparatus, it is easy to control the reaction. The carbon-containing substance is not limited to particular substances, and examples thereof include elementary carbon, a carbon compound, carbon-containing gas, carbon monoxide (CO) gas, and hydrocarbon gas. The elementary carbon may be, for example, solid elementary carbon. The solid elementary carbon is not particularly limited, and examples thereof include graphite, carbon nanotube, and fullerene. The carbon compound can be, for example, a solid carbon compound. As described above, the carbon compound may be in the form of liquid or gas. Examples of the carbon-containing gas include the hydrocarbon gas, an aliphatic oxygen compound, an aromatic oxygen compound, a nitrogen compound, and a sulfur compound. In the case where the carbon-containing substance is hydrocarbon, the hydrocarbon may be, for example, saturated hydrocarbon or unsaturated hydrocarbon, and the examples thereof include chain hydrocarbon (alkane, alkene, alkyne, etc.), alicyclic hydrocarbon, and aromatic hydrocarbon. The chain hydrocarbon may be saturated chain hydrocarbon or unsaturated chain hydrocarbon and may be straight chain hydrocarbon or branched chain hydrocarbon. The number of carbons in the chain hydrocarbon is not particularly limited, and may be, for example, 1 C to 100 C or more. The hydrocarbon is not limited to the chain hydrocarbon, and is preferably in the form of gas at the reaction temperature (for example about 1,200° C. although it is not limited) in the Group III nitride crystal generation step, for example. The boiling point of 100 C straight chain alkane(hectane) is about 721° C. at normal pressure (1 atm). Examples of the chain hydrocarbon include methane, ethane, propane, butane, 2-methylpropane, ethylene, acetylene(ethyne), propylene, 1,3-butadiene, and 1,2-butadiene. The alicyclic hydrocarbon may be saturated hydrocarbon or unsaturated hydrocarbon, may be monoring hydrocarbon or fused ring hydrocarbon, having 3 C to 100 C, for example, and may have or may not have a side chain. Examples of the alicyclic hydrocarbon include cyclopentane, cyclohexane, cycloheptane, methyl cyclohexane, and cyclohexene. The aliphatic oxygen compound or the aromatic oxygen compound is not limited to particular compounds, and examples thereof include alcohol, ether, and ketone, and specific examples thereof include ethyl acetate, diethyl ether, phenol, and diphenyl ether. The nitrogen compound is not limited to particular compounds, and examples thereof include alkyl amines and aniline. The sulfur compound is not limited to particular compounds, and can be, for example, sulfoxide, and can specifically be, for example, dimethylsulfoxide (DMSO) and the like.

In the present invention, a Group III nitride crystal of high quality with few defects can be produced by performing the reaction in the presence of a carbon-containing substance in the Group III nitride crystal generation step. The reason (mechanism) therefor can be assumed, for example, as follows although it is unknown. That is, it is assumed that, when oxide (e.g., H₂O gas) contained in the Group III element-containing gas as impurity is reduced by the carbon-containing substance and removed, the impurity in the Group III nitride crystal to be generated is reduced and the defects such as a dislocation, a crack, and the like in a crystal are reduced. The binding energy of C—O single bond is 1076 kJ/mol and the binding energy of H—O single bond of a H₂O molecule is 497 kJ/mol, which means that the C—O single bond is more stable. Thus, commonly, it is assumed that the carbon-containing substance is a substance having higher reducing power than H₂O. These assumptions, however, do not limit the present invention by any means.

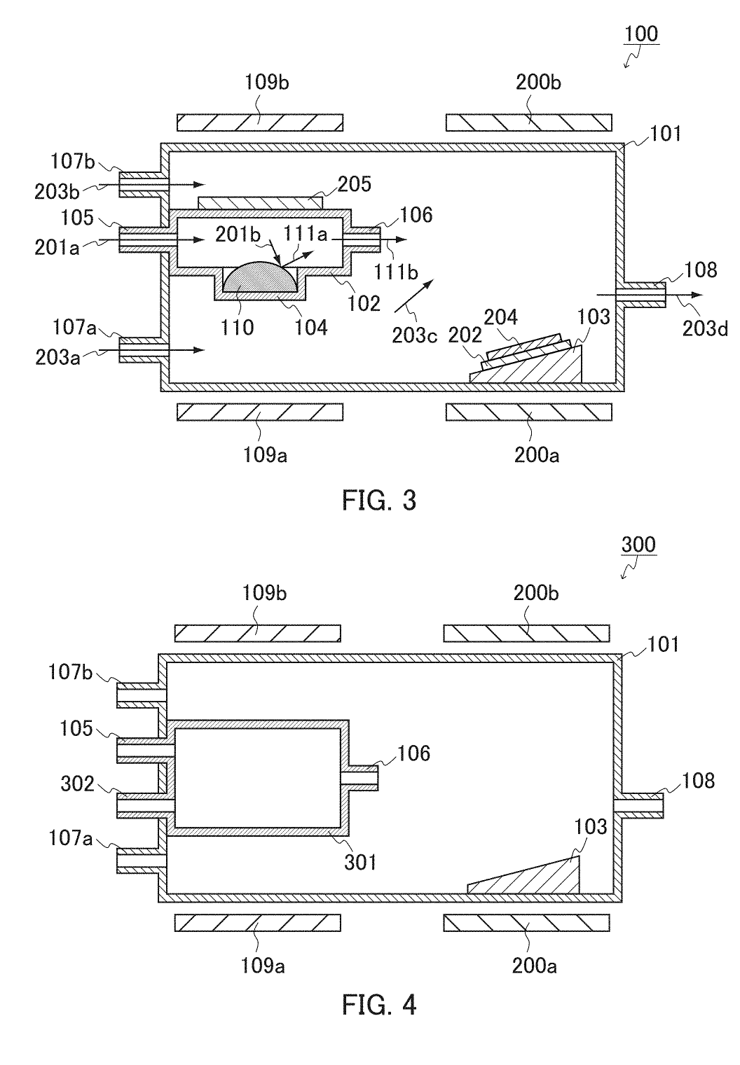

The usage of the carbon-containing substance is not limited to particular usages. For example, carbon-containing gas (methane gas, etc.) may be used as the carbon-containing substance and the carbon-containing gas may be introduced after being mixed with the nitrogen-containing gas 203a and 203b (or 203f). In addition to or instead of this, for example, as shown in FIG. 3, solid carbon (e.g., graphite sheet) 205 may be provided on the passage of the nitrogen-containing gas (on second container 102 in FIG. 3). The amount of the carbon-containing substance to be used is not particularly limited, and can be adjusted appropriately. From the view point of producing a Group III nitride crystal of high quality with few detects, the larger the amount of the carbon-containing substance to be used, the better. However, from the viewpoint of costs and the like, not too much carbon-containing substance should be used. When the carbon-containing substance is carbon-containing gas, the flow rate of the carbon-containing gas is, for example, in the range from 0.0001 to 50 Pa·m³/s, preferably in the range from 0.001 to 10 Pa·m³/s, and more preferably in the range from 0.002 to 2 Pa·m³/s. If H₂O gas is generated by the reaction according to the reaction formula (II), the molar ratio (mass ratio) C/H₂O between the number of carbon atoms (C) in the carbon-containing gas and the generation amount of the H₂O gas is not particularly limited, and is, for example, in the range from 0.001 to 5000, 0.01 to 500, or 0.1 to 100.

In the Group III nitride crystal generation step, the temperature of the substrate (i.e., crystal growth temperature) is not particularly limited. From the viewpoint of ensuring the generation rate of crystal and improving crystallinity, the temperature is preferably in the range from 700° C. to 1500° C., more preferably in the range from 1000° C. to 1400° C., and still more preferably in the range from 1100° C. to 1350° C. As described above, preferably, the method for producing a Group III nitride crystal includes an early stage crystal growth step and a late stage crystal growth step and the crystal growth temperature in the late stage crystal growth step is higher than the crystal growth temperature in the early stage crystal growth step. In this case, the crystal growth temperature in the early stage crystal growth step is, for example, in the range from 700° C. to 1400° C., preferably in the range from 900° C. to 1300° C., and more preferably in the range from 000° C. to 1200° C. The crystal growth temperature in the late stage crystal growth step is, for example, in the range from 1000° C. to 1500° C., preferably in the range from 1100° C. to 1400° C., and more preferably in the range from 1200° C. to 1350° C. Moreover, the crystal growth temperature in the early stage crystal growth step is preferably equal to or higher than the crystal growth temperature in the substrate production step.

The Group III nitride crystal generation step may be performed in a condition under pressure, in a condition under reduced pressure, or in conditions other than these conditions. The pressure in the condition under pressure is not particularly limited, and is preferably in the range from 1.01×10⁵ to 1.50×10⁷ Pa, more preferably in the range from 1.05×10⁵ to 5.00×10⁶ Pa, and still more preferably in the range from 1.10×10⁵ to 9.90×10⁵ Pa. The pressure in the condition under reduced pressure is not particularly limited, and is preferably in the range from 1×10¹ to 1×10⁵ Pa, more preferably in the range from 1×10² to 9×10⁴ Pa, and still more preferably in the range from 5×10³ to 7×10⁴ Pa.

In the Group III nitride crystal generation step, the supply amount of the Group III element metal oxidation product gas (e.g., Ga₂O gas indicated by 111b in FIGS. 2, 5, and 7) is, for example, in the range from 5×10⁻⁵ to 5×10¹ mol/h, preferably in the range from 1×10⁻⁴ to 5 mol/h, and more preferably in the range from 2×10⁻⁴ to 5×10⁻¹ mol/h. The supply amount of the Group III element metal oxidation product gas can be adjusted, for example, by adjusting the flow rate of the first carrier gas in generation of Group III element metal oxidation product gas.

The flow rate of the nitrogen-containing gas can be set appropriately according to the conditions such as the temperature of the substrate and the like. The flow rate of the nitrogen-containing gas is, for example, in the range from 0.1 to 150 Pa·m³/s, preferably in the range from 0.3 to 60 Pa·m³/s, and more preferably in the range from 0.5 to 30 Pa·m³/s.

For transferring the introduced nitrogen-containing gas to a crystal generation region (in the vicinity of the substrate support 103 in the first container 101 in FIGS. 1 to 7), second carrier gas may be introduced. For example, as shown in FIGS. 6 and 7, the second carrier gas may be introduced from a carrier gas introduction pipe (107c in FIGS. 6 and 7) provided separately from the nitrogen-containing gas introduction pipe or introduced from the nitrogen-containing gas introduction pipe after being mixed with the nitrogen-containing gas. As the second carrier gas (carrier gas 203e and 203g in FIG. 7), for example, the examples described for the first carrier gas can be used. The position where the carrier gas introduction pipe is disposed is not limited, and, for example, as in the case of the carrier gas introduction pipe 107c shown in FIGS. 6 and 7, the second carrier gas may be delivered from the periphery of the end of the second container 102 (outlet of Group III element-containing gas). This inhibits or prevents the generated Group III nitride (e.g., GaN) from being deposited at the end of the second container 102 (outlet of Group III element-containing gas) and the end of the second container 102 from being clogged with the deposited Group III nitride, for example.

In the case of introducing the second carrier gas from the carrier gas introduction pipe, the flow rate of the second carrier gas can be set appropriately according to the flow rate of the nitrogen-containing gas and the like. The flow rate of the second carrier gas is, for example, in the range from 0.1 to 150 Pa·m³/s, preferably in the range from 0.8 to 60 Pa·m³/s, and more preferably in the range from 1.5 to 30 Pa·m³/s.

The mixing ratio A:B (volume ratio) between the nitrogen-containing gas (A) and the second carrier gas (B) is not particularly limited, and is preferably in the range from 2 to 80:98 to 20, more preferably in the range from 5 to 60:95 to 40, and still more preferably in the range from 10 to 40:90 to 60. The mixing ratio A:B (volume ratio) can be set, for example, by preliminarily mixing the nitrogen-containing gas and the second carrier gas at a predetermined mixing ratio or adjusting the flow rate (partial pressure) of the nitrogen-containing gas and the flow rate (partial pressure) of the second carrier gas.

Preferably, the Group III nitride crystal (e.g., GaN crystal) generation step is performed in a condition under pressure. The pressure in the condition under pressure is as described above. The method of applying pressure can be, for example, a method of applying pressure by the nitrogen-containing gas, the second carrier gas, or the like.

The Group III nitride crystal generation step may be performed in a dopant-containing gas atmosphere. This allows a dopant-containing GaN crystal to be generated. Examples of the dopant include Si, S, Se, Te, Ge, Fe, Mg, and Zn. One type of the dopants may be used alone or two or more of them may be used in combination. Examples of the dopant-containing gas include monosilane (SiH₄), disilane (Si₂H₆), triethylsilane (SiH(C₂H₅)₃), tetraethylsilane Si(C₂H₅)₄), H₂S, H₂Se, H₂Te, GeH₄, Ge₂O, SiO, MgO, and ZnO, and one of them may be used alone or two or more of them may be used in combination.

For example, the dopant-containing gas may be introduced from a dopant-containing gas introduction pipe (not shown) provided separately from the nitrogen-containing gas introduction pipe or introduced from the nitrogen-containing gas introduction pipe after being mixed with the nitrogen-containing gas. In the case of introducing the second carrier gas, the dopant-containing gas may be introduced after being mixed with the second carrier gas.

The concentration of the dopant in the dopant-containing gas is not particularly limited, and is, for example, in the range from 0.001 to 100000 ppm, preferably in the range from 0.01 to 1000 ppm, and more preferably in the range from 0.1 to 10 ppm.

The generation rate of the Group III nitride crystal (e.g., GaN crystal) is not particularly limited. The rate is, for example, 100 μm/h or more, preferably 500 μm/h or more, and more preferably 1000 μm/h or more.

The Group III nitride crystal production method (A) can be performed as described above. However, the Group III nitride crystal production method (A) is not limited thereto. For example, as described above, in the Group III nitride crystal production method (A), preferably, a reaction is performed also in the presence of reducing gas in a reaction system. Furthermore, as described above, preferably, at least one of the oxidizing gas and the nitrogen-containing gas is mixed with the reducing gas. That is, in FIG. 2, 5, or 7, at least one of nitrogen-containing gas 203a and 203b (or 203f) and oxidizing gas 201a (or 401a) may be mixed with the reducing gas. In the production method of the present invention, more preferably, the oxidizing gas is mixed with the reducing gas. Thereby, for example, in the Group III element metal oxidation product gas generation step, the generation of a by-product in the reaction of the Group III element metal and the oxidizing gas can be inhibited and the reaction efficiency (the generation efficiency of the Group III element metal oxidation product gas) can further be improved. Specifically, for example, in the reaction of gallium (the Group III element metal) and H₂O gas (the oxidizing gas), by mixing H₂O gas with H₂ gas (the reducing gas), the generation of Ga₂O₃, which is a by-product, can be inhibited and the generation efficiency of Ga₂O gas (the Group III element metal oxidation product gas) can further be improved.

Furthermore, in the Group III nitride crystal production method (A), when the reaction is performed in the presence of the reducing gas in a reaction system, for example, a larger Group III nitride crystal can be produced. For example, by growing a Group III nitride crystal on a seed crystal and then slicing the Group III nitride crystal, a plate-like semiconductor wafer formed of a Group III nitride crystal is produced. However, the Group III nitride crystal tends to have a tapered pyramid shape as it grows, and thus only a small semiconductor wafer is obtained at the tip of the pyramid-shaped crystal. It is to be noted that, in the production method of the present invention, when the reaction is performed in the presence of the reducing gas in a reaction system, a columnar (i.e., not tapered) crystal instead of a pyramid-shaped crystal tends to be obtained although the reason is unknown. Different from a pyramid-shaped crystal, when such a columnar Group III nitride crystal is sliced, semiconductor wafers (Group III nitride crystals) each having a large diameter can be obtained in most parts.

In the Group III nitride crystal production method (A), examples of the reducing gas include hydrogen gas; carbon monoxide gas; hydrocarbon gas such as methane gas, ethane gas, or the like; hydrogen sulfide gas; and sulfur dioxide gas, and one of them may be used alone or two or more of them may be used in combination. Among them, hydrogen gas is particularly preferable. The hydrogen gas with high purity is preferable. The purity of the hydrogen gas is particularly preferably 99.9999% or more.

When the Group III element metal oxidation product gas generation step is performed in the presence of the reducing gas, the reaction temperature is not particularly limited. From the viewpoint of inhibiting generation of a by-product, the reaction temperature is preferably 900° C. or higher, more preferably 1000° C. or higher, and still more preferably 1100° C. or higher. The upper limit of the reaction temperature is not particularly limited, and is, for example, 1500° C. or lower.

When the reducing gas is used in the Group III nitride crystal production method (A), the amount of the reducing gas to be used is not particularly limited. The amount of the reducing gas relative to the total volume of the oxidizing gas and the reducing gas is, for example, in the range from 1 to 99 vol. %, preferably in the range from 3 to 80 vol. %, and more preferably in the range from 5 to 70 vol. %. The flow rate of the reducing gas can be set appropriately according to the flow rate of the oxidizing gas or the like. The flow rate of the reducing gas is, for example, in the range from 0.01 to 100 Pa·m³/s, preferably in the range from 0.05 to 50 Pa·m³/s, and more preferably in the range from 0.1 to 10 Pa·m³/s. Furthermore, as described above, generation of Group III element metal oxidation product gas 111a (111b) is preferably performed in a condition under pressure. The pressure is, for example, as described above. The method of applying pressure may be, for example, a method of applying pressure by the oxidizing gas and the reducing gas.

The Group III nitride crystal production method (A) of the present invention is vapor phase epitaxy and can be performed without using halide as a material. When halide is not used, different from the halide vapour phase epitaxy described in S52(1977)-023600 A (Patent Document 1) and the like, a Group III nitride crystal can be produced without generating a halogen-containing by-product. This makes it possible to prevent crystal generation from being adversely affected due to clogging of the exhaust pipe of the production apparatus with a halogen-containing by-product (e.g., NH₄Cl), for example.

### 2-3. Production Steps, Reaction Conditions, and the Like in Group III Nitride Crystal Production Method (B)

Next, production steps, reaction conditions, and the like in the Group III nitride crystal production method (B) are described with reference to an illustrative example.

The Group III nitride crystal production method (B) can be performed using the production apparatus 100 shown in FIG. 1 or 6, for example. Specifically, the Group III element metal placement part 104 is used as a Group III element oxide placement part 104. The oxidizing gas introduction pipe 105 is used as a reducing gas introduction pipe 105. The Group III element metal oxidization product gas delivery pipe 106 is used as a reduced product gas delivery pipe 106.

The Group III nitride crystal production method (B) is described specifically below using FIG. 2 with reference to the case in which the Group III nitride crystal production method (B) is performed using the production apparatus shown in FIG. 1 or 6, Ga₂O₃ is used as Group III element oxide, Ga₂O gas is used as reduced product gas, hydrogen gas is used as reducing gas, ammonia gas is used as nitrogen-containing gas, and a Group III nitride crystal to be produced is a GaN crystal as an example. It is to be noted, however, that the Group III nitride crystal production method (B) is not limited to the following example. As described above, the Group III nitride crystal production method (B) includes a Group III element-containing gas generation step (reduced product gas generation step) and a Group III nitride crystal generation step.

First, Ga₂O₃ is placed on the Group III element oxide placement part 104, and a substrate 202 is set on the substrate support 103. Next, the Ga₂O₃ is heated using the first heating units 109a and 109b, and the substrate 202 is heated using the first heating units 200a and 200b. In this state, hydrogen gas 201a is introduced from the reducing gas introduction pipe 105, and ammonia gas 203a and 203b is introduced from the nitrogen-containing gas introduction pipes 107a and 107b. The introduced hydrogen gas 201b reacts with the Ga₂O₃, thereby generating Ga₂O gas (the following formula (III)). The thus-generated Ga₂O gas 111a is delivered to the outside of the second container 102 as Ga₂O gas 111b through the reduced product gas delivery pipe 106. The delivered Ga₂O gas 111b reacts with the introduced ammonia gas 203c, thereby generating a GaN crystal 204 on the substrate 202 (the following formula (IV)).

Ga₂O₃+2H₂→Ga₂O+2H₂O (III)

Ga₂O+2NH₃→2GaN+2H₂O+2H₂ (IV)

The present invention is, as described above, characterized in that the reaction is performed in the presence of a carbon-containing substance in the Group III nitride crystal generation step. In the Group III nitride crystal production method (B), the usage of the carbon-containing substance is not limited to particular usages and can be, for example, the same as in the Group III nitride crystal production method (A). That is, for example, carbon-containing gas (methane gas, etc.) may be used as the carbon-containing substance and the carbon-containing gas may be introduced after being mixed with the nitrogen-containing gas 203a and 203b (or 203g). In addition to or instead of this, for example, as shown in FIG. 3, solid carbon (e.g., graphite sheet) 205 may be provided on the passage of the nitrogen-containing gas (on second container 102 in FIG. 3). The type of the carbon-containing substance, the amount of the carbon-containing substance to be used, and the reason (mechanism) for achievement of a Group III nitride crystal of high quality with few defects, and the like are not particularly limited, and can be, for example, the same as described in the Group III nitride crystal production method (A).

As can be seen from the formulae (III) and (IV), by-products generated in the Group III nitride crystal production method (B) are only water and hydrogen. That is, no solid by-product is generated. The water and the hydrogen can be exhausted from the exhaust pipe 108 in the state of gas or liquid, for example. As a result, for example, a GaN crystal can be grown for a long period, whereby a large and thick GaN crystal can be obtained. Moreover, for example, it is not necessary to provide a filter or the like for removing by-products, which is advantageous in terms of cost. It is to be noted, however, that the Group III nitride crystal production method (B) is not limited by the above description.

Preferably, the Ga₂O₃ is in the form of a powder or a granule. When the Ga₂O₃ is in the form of a powder or a granule, the Ga₂O₃ has a large surface area, which promotes the generation of Ga₂O gas.

For generating a ternary or higher nitride crystal, it is preferable to generate reduced product gas of at least two kinds of Group III element oxides. In this case, it is preferable to use a production apparatus provided with at least two second containers.

The hydrogen gas with high purity is preferable. The purity of the hydrogen gas is preferably 99.9999% or more. The flow rate (partial pressure) of the hydrogen gas can be set as appropriate according to the conditions such as the temperature of the Ga₂O₃ and the like. The partial pressure of the hydrogen gas is, for example, in the range from 0.2 to 2000 kPa, preferably in the range from 0.5 to 1000 kPa, and more preferably in the range from 1.5 to 500 kPa.

As described above, from the viewpoint of controlling the partial pressure of the hydrogen gas, preferably, the generation of Ga₂O gas is performed in an atmosphere of mixed gas of the hydrogen gas and inert gas. Examples of the method for creating the mixed gas atmosphere include a method of introducing inert gas from an inert gas introduction pipe (not shown) provided in the second container separately from the reducing gas introduction pipe; and a method of preliminarily generating gas in which the hydrogen gas and the inert gas are mixed at predetermined proportions and introducing the thus obtained gas from the reducing gas introduction pipe. In the case of introducing the inert gas from the separately provided inert gas introduction pipe, the flow rate (partial pressure) of the inert gas can be set as appropriate according to the flow rate of the hydrogen gas and the like. The partial pressure of the inert gas is, for example, in the range from 0.2 to 2000 kPa, preferably in the range from 2.0 to 1000 kPa, and more preferably in the range from 5.0 to 500 kPa.

The proportion of the hydrogen gas and the proportion of the inert gas in the mixed gas are as described above. The proportion of the hydrogen gas and the proportion of the inert gas in the mixed gas can be set, for example, by preliminarily generating the mixed gas in which the hydrogen gas and the inert gas are mixed at predetermined proportions or by adjusting the flow rate (partial pressure) of the hydrogen gas and the flow rate (partial pressure) of the inert gas.

For delivering the Ga₂O gas to the outside of the second container through the reduced product gas delivery pipe, first carrier gas may be introduced. As the first carrier gas, for example, the examples described for the inert gas can be used. The flow rate (partial pressure) of the first carrier gas can be the same as that of the inert gas. In the case of introducing the inert gas, the inert gas can be used as the first carrier gas.

Preferably, the generation of Ga₂O gas is performed under pressure. The pressure in the condition under pressure is not particularly limited, and is preferably in the range from 1.01×10⁵ to 1.50×10⁷ Pa, more preferably in the range from 1.05×10⁵ to 5.00×10⁶ Pa, and still more preferably in the range from 1.10×10⁵ to 9.90×10⁵ Pa. The method of applying pressure can be, for example, a method of applying pressure by the hydrogen gas, the first carrier gas, or the like.

When reduced product gas of at least two kinds of Group III element oxides is generated as described above, a ternary or higher nitride crystal is generated on a substrate, for example. The ternary or higher nitride crystal can be, for example, a crystal represented by GaₓIn₁₋ₓN (0<x<1).

The supply amount of the Ga₂O gas is, for example, in the range from 5×10⁻⁵ to 1×10⁻¹ mol/h, preferably in the range from 1×10⁻⁴ to 1×10⁻² mol/h, and more preferably in the range from 2×10⁻⁴ to 5×10⁻⁴ mol/h. The supply amount of the Ga₂O gas can be adjusted, for example, by adjusting the flow rate (partial pressure) of the first carrier gas in generation of the Ga₂O gas.

The flow rate (partial pressure) of the ammonia gas can be set as appropriate according to the conditions such as the temperature of the substrate and the like. The partial pressure of the ammonia gas is, for example, in the range from 0.2 to 3000 kPa, preferably in the range from 0.5 to 2000 kPa, and more preferably in the range from 1.5 to 1000 kPa.

For transferring the introduced ammonia gas to a crystal generation region, second carrier gas may be introduced. For example, the second carrier gas may be introduced from a carrier gas introduction pipe (not shown) provided separately from the nitrogen-containing gas introduction pipe or introduced from the nitrogen-containing gas introduction pipe after being mixed with the ammonia gas. As the second carrier gas, for example, the examples described for the first carrier gas can be used.

In the case of introducing the second carrier gas from the carrier gas introduction pipe, the flow rate (partial pressure) of the second carrier gas can be set as appropriate according to the flow rate (partial pressure) of the nitrogen-containing gas and the like. The partial pressure of the second carrier gas is, for example, in the range from 0.2 to 3000 kPa, preferably in the range from 0.5 to 2000 kPa, and more preferably in the range from 1.5 to 1000 kPa.

The mixing ratio A:B (volume ratio) between the ammonia gas (A) and the second carrier gas (B) is not particularly limited, and is preferably in the range from 3 to 80:97 to 20, more preferably in the range from 8 to 60:92 to 40, and still more preferably in the range from 10 to 40:90 to 60. The mixing ratio A:B (volume ratio) can be set, for example, by preliminarily mixing the ammonia gas and the second carrier gas at a predetermined mixing ratio or adjusting the flow rate (partial pressure) of the ammonia gas and the flow rate (partial pressure) of the second carrier gas.

Preferably, the GaN crystal generation is performed in a condition under pressure. The pressure in the condition under pressure is as described above. The method of applying pressure can be, for example, a method of applying pressure by the ammonia gas, the second carrier gas, or the like.

The generation of a GaN crystal may be performed in a dopant-containing gas atmosphere. This allows a dopant-containing GaN crystal to be generated. Examples of the dopant include Si, S, Se, Te, Ge, Fe, Mg, and Zn. One type of the dopants may be used alone or two or more of them may be used in combination. Examples of the dopant-containing gas include monosilane (SiH₄), disilane (Si₂H₆), triethylsilane (SiH(C₂H₅)₃), tetraethylsilane Si(C₂H₅)₄), H₂S, H₂Se, H₂Te, GeH₄, Ge₂O, SiO, MgO, and ZnO, and one of them may be used alone or two or more of them may be used in combination.

For example, the dopant-containing gas may be introduced from a dopant-containing gas introduction pipe (not shown) provided separately from the nitrogen-containing gas introduction pipe or introduced from the nitrogen-containing gas introduction pipe after being mixed with the ammonia gas. In the case of introducing the second carrier gas, the dopant-containing gas may be introduced after being mixed with the second carrier gas.

The concentration of the dopant in the dopant-containing gas is not particularly limited, and is, for example, in the range from 0.001 to 100000 ppm, preferably in the range from 0.01 to 1000 ppm, and more preferably in the range from 0.1 to 10 ppm.

The generation rate of the GaN crystal is not particularly limited. The rate is, for example, 100 μm/h or more, preferably 500 μm/h or more, and more preferably 1000 μm/h or more.

Also in the case of using any Group III element oxide other than Ga₂O₃, the production method of the present invention can generate a Group III nitride crystal in the same manner as in the case of using Ga₂O₃.

The Group III element oxide other than the Ga₂O₃ may be as follows: when the Group III element is In, the Group III element oxide can be, for example, In₂O₃; when the Group III element is Al, the Group III element oxide can be, for example, Al₂O₃; when the Group III element is B, the Group III element oxide can be, for example, B₂O₃; and when the Group III element is Tl, the Group III element oxide can be, for example, Tl₂O₃. One of the Group III element oxides other than the Ga₂O₃ may be used alone, or two or more of them may be used in combination.

### 2-4. Group III Nitride Crystal and the Like Produced by Group III Nitride Crystal Production Method (A) or (B)

There is no particular limitation on the size of the Group III nitride crystal produced by the method for producing a Group III nitride crystal. Preferably, the major axis is 15 cm (about 6 inch) or more, more preferably, the major axis is 20 cm (about 8 inch) or more, and particularly preferably, the major axis is 25 cm (about 10 inch) or more, for example. There is no particular limitation on the height of the Group III nitride crystal. The height is, for example, 1 cm or more, preferably 5 cm or more, and more preferably 10 cm or more. The production method according to the present invention however is not limited to the production of such a large Group III nitride crystal. For example, the production method according to the present invention can be used for producing a Group III nitride crystal of higher quality having a conventional size. Furthermore, for example, as described above, the height (thickness) of the Group III nitride crystal is not particularly limited.

In the Group III nitride crystal, the dislocation density is not particularly limited and is preferably 1.0×10⁷ cm⁻² or less, more preferably 1.0×10⁴ m⁻² or less, still more preferably 1.0×10³ cm⁻² or less, and still more preferably 1.0×10² cm⁻² or less. Although the dislocation density is ideally 0, it is normally impossible for the dislocation density to be 0. Thus, for example, the dislocation density is a value more than 0 and is particularly preferably not more than a measurement limit of a measurement instrument. The dislocation density may be, for example, an average value of the entire crystal, and, more preferably, the maximum value in the crystal is not more the above-described value. In the Group III nitride crystal of the present invention, the half width of each of a symmetric reflection component (002) and an asymmetric reflection component (102) by XRC is, for example, 300 seconds or less, preferably 100 seconds or less, more preferably 30 seconds or less, and ideally 0.

For example, the Group III nitride crystal production method of the present invention may further include a crystal re-growth step of further growing the produced Group III nitride crystal. Specifically, for example, in the crystal re-growth step, the produced Group III nitride crystal may be cut so that any plane (for example, c-, m-, or a-plane or another nonpolar plane) is exposed, and the Group III nitride crystal may be further grown using the plane as a crystal growth plane. Thus, a Group III nitride crystal having a large area of any plane and a large thickness can be produced.

### 3. Group III Nitride Crystal and Semiconductor Apparatus

The Group III nitride crystal of the present invention is a Group III nitride crystal produced by the production method of the present invention or a Group III nitride crystal produced by further growing the Group III nitride crystal. The Group III nitride crystal of the present invention is, for example, a large Group III nitride crystal of high quality with few defects. Although the quality is not particularly limited, for example, the dislocation density is preferably in the above-described numerical range. The size of the Group III nitride crystal also is not particularly limited and is, for example, as mentioned above. The use of the Group III nitride crystal of the present invention also is not particularly limited and can be used in a semiconductor apparatus since it has properties of a semiconductor, for example. In the present invention, the Group III nitride crystal is not limited to particular crystals and is a Group III nitride crystal represented by AlₓGa_{y}In_{1-x-y}N (0≦x≦1, 0≦y≦1, x+y≦1), and examples thereof include AlGaN, InGaN, InAlGaN. Among them, GaN is particularly preferable. The Group III element is, for example, at least one selected from the group consisting of gallium (Ga), indium (In), and aluminum (Al). Among them, Ga is particularly preferable.

According to the present invention, as mentioned above, a Group III nitride (e.g., GaN) crystal with a diameter of 6 inches or more, which has not been produced by a conventional technique, can be provided. Accordingly, for example, by using Group III nitride as a substitute for Si in a semiconductor apparatus such as a power device, a high frequency device, or the like generally required to have a large diameter of Si (silicon), the performance can further be improved. Therefore, the present invention has a great impact on the semiconductor industry. The application of the Group III nitride crystal of the present invention is not limited thereto and is applicable to any other semiconductor apparatuses such as solar battery and the like and any other applications besides the semiconductor apparatuses.

The semiconductor apparatus of the present invention is not limited to particular apparatuses, and the semiconductor apparatus can be any article as long as it is operated by using a semiconductor. Examples of the article operated by a semiconductor include semiconductor devices and electrical equipment using the semiconductor device. Examples of the semiconductor device include diodes, high frequency devices such as transistors, power devices, and light emitting devices such as light-emitting diodes (LEDs) and laser diodes (LDs). Examples of the electrical equipment using the semiconductor device include a cellular phone base station equipped with the high frequency device; control equipment for solar cell and power supply control equipment of a vehicle driven by electricity each equipped with the power device; and a display, lighting equipment, and an optical disk device each equipped with the light emitting device. For example, a laser diode (LD) that emits blue light is applied to a high density optical disk, a display, and the like, and a light-emitting diode (LED) that emits blue light is applied to a display, a lighting, and the like. An ultraviolet LD is expected to be applied in biotechnology and the like and an ultraviolet LED is expected as an ultraviolet source which is an alternate for a mercury lamp. Also, an inverter that uses the Group III-V compound of the present invention as a power semiconductor for inverter can be used for power generation in a solar cell, for example. As described above, the Group III nitride crystal of the present invention is not limited thereto, and can be applied to any other semiconductor apparatuses or various technical fields besides the semiconductor apparatuses.

### EXAMPLES

The examples of the present invention are described below. The present invention, however, is not limited by the following examples.

In the Examples below, the XRC half width was measured using a SmartLab (product name) produced by Rigaku Corporation. The dislocation density was measured according to the evaluation of the etch pit density generated by KOH+NaOH melt etching.

### Example 1

In the present Example, a GaN crystal was generated by vapor phase epitaxy by using solid carbon (graphite) as a carbon-containing substance (Group III nitride crystal growth step), and was further grown, thereby producing an intended GaN crystal.

### Production of GaN Crystal by Vapor Phase Epitaxy

First, as a GaN seed crystal, 2-inch free-standing substrate produced by FKK Corporation was prepared. Next, on the GaN seed crystal (GaN crystal layer substrate), a GaN crystal was produced by vapor phase epitaxy (homoepi) using the apparatus shown in FIG. 1 (FIG. 3).

The vapor phase epitaxy was performed as follows. In the present Example, powdery gallium oxide (III) (Ga₂O₃) was used as a Group III element-containing material 110 and hydrogen gas (H₂) was used as reduced product gas 201a. The partial pressure of the hydrogen gas (H₂) was 3.3 kPa. In this state, the hydrogen gas 201a (201b) was caused to react with gallium oxide (III) 110 to generate gallium oxide (I) (Ga₂O) gas 111a (111b). In the present Example, the generation amount of Ga₂O (gallium oxide (I)) was calculated based on the mass change (decrease amount) of Ga₂O₃ before and after the reaction with the conversion efficiency from H₂ and Ga₂O₃ to Ga₂O being estimated as 100%. According to this calculation, the partial pressure of the gallium oxide (I) gas 111a (111b) was estimated as 2×10⁻² kPa. Furthermore, ammonia gas (NH₃) was used as nitrogen-containing gas 203a and 203b. The partial pressure of the ammonia gas was 67 kPa. Moreover, N₂ gas (100% N₂ gas, containing no other gas) as carrier gas was introduced from the oxidizing gas introduction pipe 105 and nitrogen-containing gas introduction pipes 107a and 107b and pressure was applied so that the total pressure becomes 100 kPa. Prior to the feeding of each gas, as shown in FIG. 3, necessary number of solid carbons 205 (graphite sheet, thickness: 0.38 mm, width: 4.7 cm, length: 14 cm, product of Toyo Tanso Co., Ltd., product name: PERMA-FOIL) were placed (provided) over another on a second container 102. Each gas was fed after setting the heating temperature with first heating units (heaters) 109a and 109b at 970° C. and the heating temperature with second heating units (heaters) 200a and 200b at 1200° C. so that the substrate temperature (crystal growth temperature) of the GaN crystal layer substrate (202 in FIG. 3) becomes 1200° C. The crystal growth time (time when each gas was kept feeding) was 45 minutes. This vapor phase epitaxy allows a GaN crystal to be produced on the GaN seed crystal (GaN crystal layer substrate).

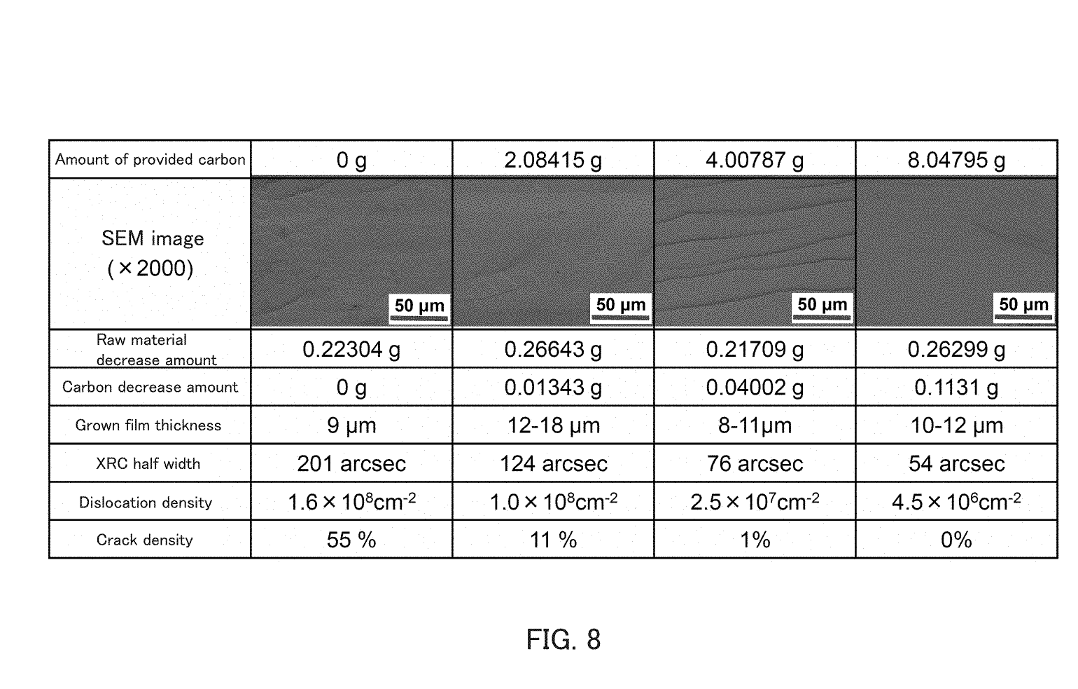

In this production method, GaN crystals were produced with different amounts of solid carbon. As a Comparative Example, a GaN crystal was produced in the same manner as in the present Example except that the solid carbon was not provided. The SEM image of each GaN crystal produced (grown) in this manner was obtained, and the film thickness, XRC half width, crack density, and dislocation density of each GaN crystal were measured. The results are shown in FIG. 8. In FIG. 8, the “amount of provided carbon” denotes the mass of the provided solid carbon. The “raw material decrease amount” denotes the decrease amount of the mass of Ga₂O₃ after production of GaN crystal (after reaction) as compared to the mass of Ga₂O₃ before reaction. The “carbon decrease amount” denotes the decrease amount of the mass of solid carbon after production of GaN crystal (after reaction) as compared to the mass of solid carbon before reaction. The “grown film thickness” denotes the film thickness of the produced (grown) GaN crystal. The “crack density” was calculated by the calculation method described below.

### Calculation Method of Crack Density

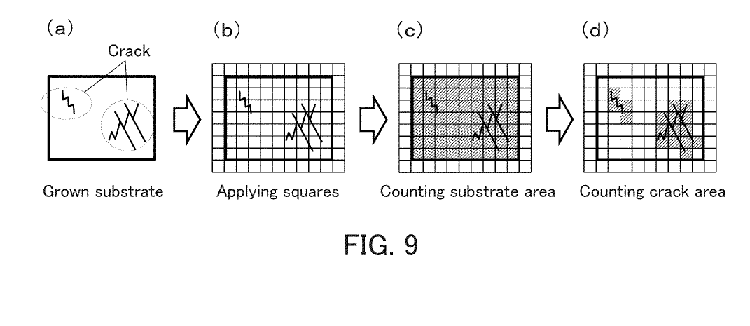

First, as shown in (a) of FIG. 9, the image of the whole surface of the grown (produced) GaN crystal was obtained with a differential interference microscope. Next, as shown in (b) of FIG. 9, squares (0.15 mm×0.15 mm) were applied to the image. Then, as shown in (c) of FIG. 9, the area of the whole surface of the grown (produced) GaN crystal (substrate area) was counted (calculated). Then, as shown in (d) of FIG. 9, the number of squares including cracks are counted (calculated) as a crack area and the crack area was divided by the area of the whole surface of the GaN crystal (substrate area) counted in (c) of FIG. 9, thereby calculating the crack density. Note that, (a) to (d) of FIG. 9 are schematic views for convenience in explanation.

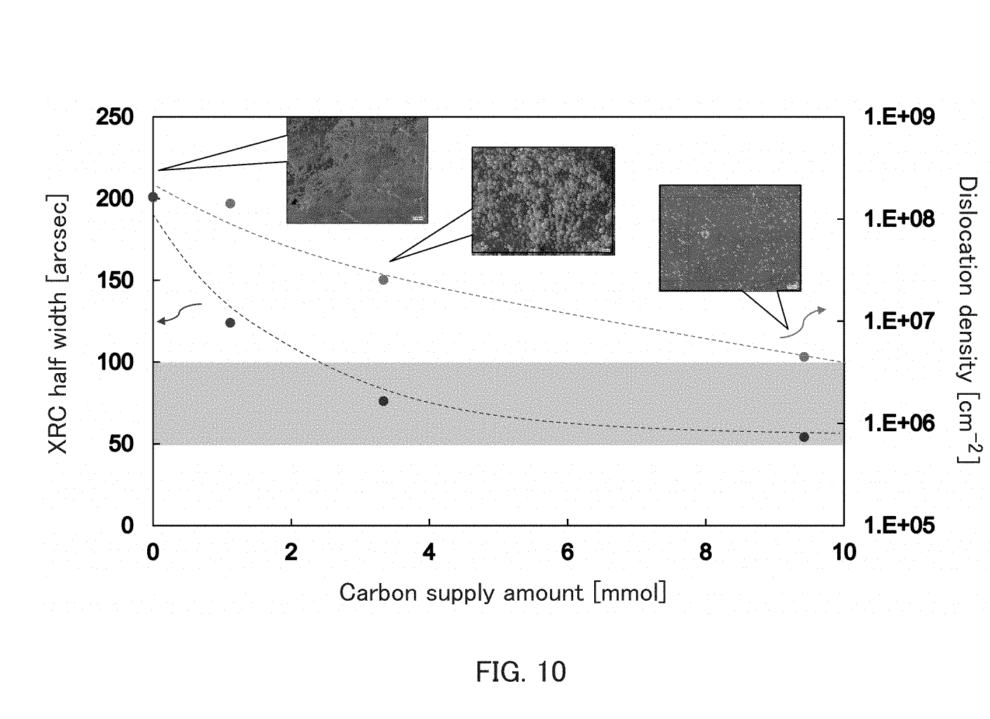

FIG. 10 is a graph showing the relationship between the carbon supply amount (decrease amount) and the XRC half width and the dislocation density in Example of FIG. 8. In FIG. 10, the horizontal axis indicates the carbon supply amount [mmol] and is a numerical value obtained by converting the “carbon decrease amount” in FIG. 8 into the mass [mmol] of carbon atom (C). The vertical axis indicates the XRC half width [arcsec] or the dislocation density [cm⁻²]. The upper curved line (dashed line) in FIG. 10 indicates the relationship between the carbon supply amount [mmol] and the XRC half width [arcsec]. The lower dashed line indicates the relationship between the carbon supply amount [mmol] and the dislocation density [cm⁻²].

As shown in FIGS. 8 to 10, as compared to the case (Comparative Example, the leftmost in FIG. 8, amount of provided carbon: 0 g) in which solid carbon was not provided, each of the cases (Example) in which solid carbon was provided showed small XRC half width, significantly small crack density, and small dislocation density. This shows that GaN crystals of high quality with few defects were obtained by the Example. In the present Example, as shown in FIG. 8, the larger the provided carbon amount, the larger the carbon decrease amount (consumption amount), thereby achieving small XRC half width, crack density, and dislocation density. In the case where the amount of provided carbon is the largest, there was no crack at all. Also, in the case where the amount of provided carbon is the largest, a crystal having a dislocation density equivalent to the seed substrate (GaN seed crystal) was obtained. As shown in the SEM image of FIG. 8, the larger the provided carbon amount, the fewer the horizontal lines or arc lines observed on the surface of the GaN crystal. This shows that bunching (phenomenon in which the step height of crystal increases due to the impurity and the like) is inhibited.

### Example 2

In the present Example, methane gas (CH₄) was used as a carbon-containing substance. Specifically, a GaN crystal was produced in the same manner as in Example 1 except that the apparatus shown in FIG. 6 (FIG. 7) was used instead of the apparatus shown in FIG. 1 (FIG. 3), methane gas was mixed with nitrogen-containing gas (ammonia gas) 203f instead of providing solid carbon, and the flow rate of each gas was set as described below. In the present Example,

feeding of gas was started during the temperature rising, the temperature rising time was 30 minutes, and the GaN crystal growth time was 60 minutes.

gas flow rate (during temperature rising)
201a:H₂ 0 sccm+N₂ 200 sccm
203e:N₂ 200 sccm
203f:NH₃ 2000 sccm+CH₄
203g:N₂ 200 sccm
gas flow rate (during GaN crystal growth)
201a:H₂ 100 sccm+N₂ 400 sccm
203e:N₂ 3000 sccm
203f:NH₃ 2000 sccm+CH₄
203g:N₂ 2000 sccm

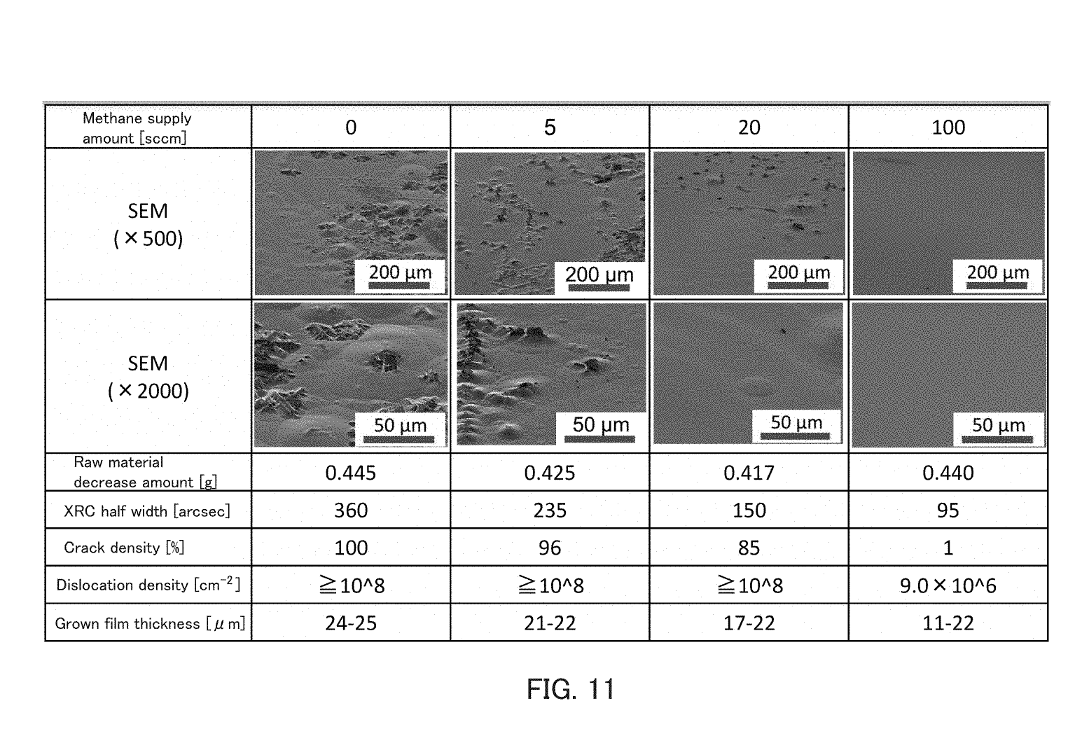

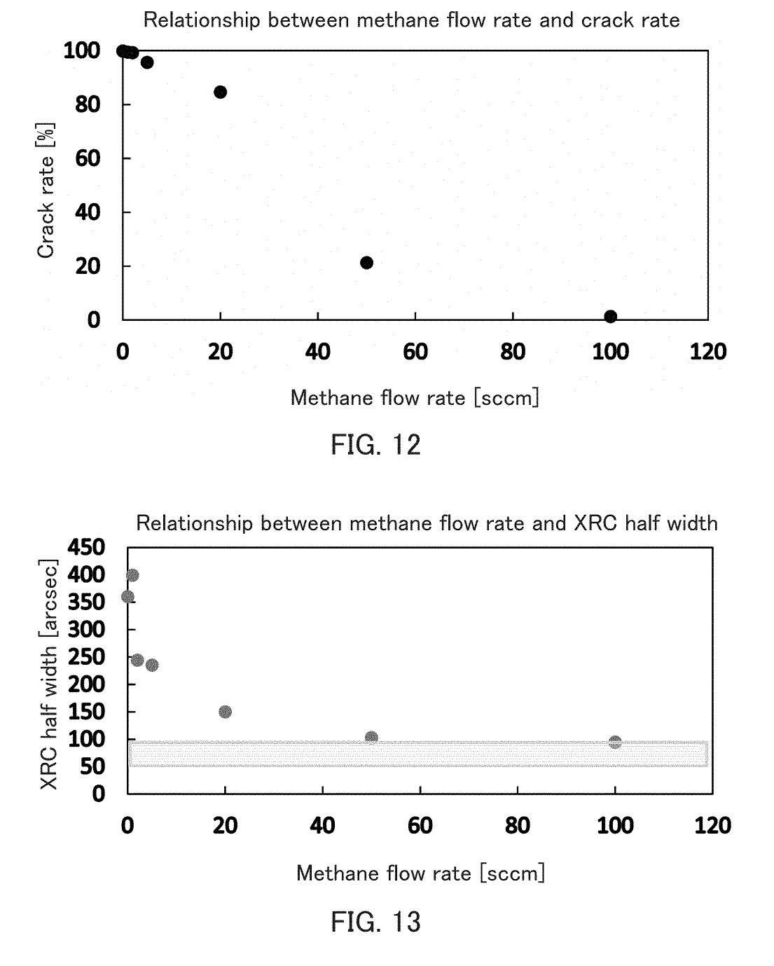

In this production method, GaN crystals were produced at different flow rates of methane (methane gas) CH₄ mixed with nitrogen-containing gas (ammonia gas) 203f. As a Comparative Example, a GaN crystal was produced in the same manner as in the present Example except that the methane gas was not used. The SEM image of each GaN crystal produced (grown) in this manner was obtained, and the film thickness, XRC half width, crack rate, and dislocation density of each GaN crystal were measured. The results are shown in FIG. 11. In FIG. 11, the leftmost example (methane supply amount: 0 sccm) shows an example (Comparative Example) in which methane gas was not used, and the other examples show Example. In FIG. 11, the meanings of the “crack density”, “raw material decrease amount”, and “grown film thickness” are the same as those in FIG. 8. The “methane supply amount” is synonymous with the methane flow rate. FIG. 12 is a graph showing the relationship between the methane flow rate and the crack rate (synonymous with a crack density) in Example of FIG. 11. In FIG. 12, the horizontal axis indicates the methane flow rate [sccm] and the vertical axis indicates the crack rate [%]. FIG. 13 is a graph showing the relationship between the methane flow rate and the XRC half width in Example of FIG. 11. In FIG. 13, the horizontal axis indicates the methane flow rate [sccm] and the vertical axis indicates the XRC half width [arcsec].

As shown in FIGS. 11 to 13, as compared to the case (Comparative Example) in which methane gas was not used, each of the cases (Example) in which methane gas was fed showed small XRC half width, significantly small crack density, and small dislocation density. This shows that GaN crystals of high quality with few defects were obtained by the Example. In the present Example, as shown in FIGS. 11 to 13, the larger the methane flow rate, the smaller the XRC half width, the crack density, and the dislocation density.

### Example 3

In the present Example, a GaN crystal was produced with the apparatus shown in FIG. 6 (FIG. 7), using metal gallium (Ga) as a raw material, and using methane gas (CH₄) as a carbon-containing substance. In the present Example, a GaN crystal was produced in the same manner as in Example 2 except that metal gallium was used instead of Ga₂O₃ and the flow rate of each gas during the GaN crystal growth was set as described below.

gas flow rate (during GaN crystal growth)
201a:H₂ 100 sccm+N₂ 400 sccm+H₂O 1.84 sccm
203e:N₂ 3000 sccm
203f:NH₃ 2000 sccm+CH₄
203g:N₂ 2000 sccm

In the present Example, a GaN crystal was produced as described below. First, as a GaN seed crystal, 2-inch free-standing substrate produced by FKK Corporation was prepared as in Examples 1 and 2.

Next, as shown in FIG. 7, the GaN seed crystal was disposed as a GaN crystal layer substrate 202. Then, the GaN crystal layer substrate 202 was heated by the first heating units (heaters) 109a and 109 and the second heating units (heaters) 200a and 200b. The heating temperature was the same as that in Example 1. Then, in this state, a mixed gas of H₂O gas (oxidizing gas) and nitrogen gas (carrier gas) was introduced from the oxidizing gas introduction pipe 105. In the mixed gas, the flow rate of the H₂O gas was 1.69×10⁻² Pa·m³/s and the flow rate of the nitrogen gas was 3.21 Pa·m³/s. The proportion of the H₂O gas in the mixed gas was 0.5 vol. % and the proportion of the nitrogen gas in the mixed gas was 99.5 vol. %. From the nitrogen-containing gas introduction pipe, gas obtained by mixing methane gas (CH₄) as a carbon-containing substance with the mixed gas of ammonia gas (A) and nitrogen gas (B) was introduced as nitrogen-containing gas. The flow rate of the ammonia gas (A) was 0.51 Pa·m³/s and the flow rate of the nitrogen gas (B) was 4.56 Pa·m³/s. The mixing ratio A:B (volume ratio) of the gas was 10:90. The flow rate of the methane gas was 0.17 Pa·m³/s (100 sccm). The generated Ga₂O gas and the introduced nitrogen-containing gas were caused to react to generate a GaN crystal on the substrate. The Ga₂O gas was generated under the following conditions. That is, the temperature of gallium was 1150° C. and the pressure was 1.00×10⁵ Pa. The GaN crystal was generated under the following conditions. That is, the supply amount of the Ga₂O gas was 1.0×10⁻³ mol/h, the temperature of the substrate was 1200° C., the pressure was 1.0×10⁵ Pa, and the reaction time was 0.5 hours. In this manner, the GaN crystal of the present Example as an epitaxial layer having a thickness of 20 to 28 μm was obtained on the GaN crystal layer substrate 202.

As a Comparative Example, a GaN crystal was produced in the same manner as in the present Example except that the methane gas was not used.

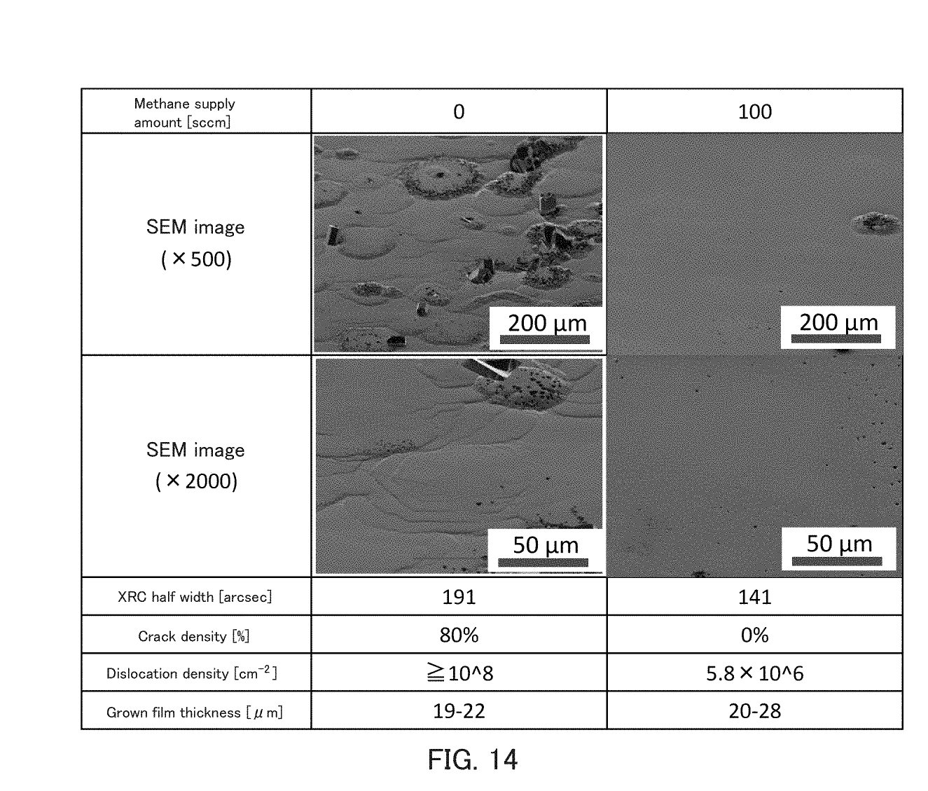

The SEM images of the GaN crystals of the present Example and the SEM image of the GaN crystal of Comparative Example in which methane gas was not used were obtained. The film thickness, XRC half width, crack density, and dislocation density of each GaN crystal were measured. The results are shown in FIG. 14. As shown in FIG. 14, as compared to the case (Comparative Example) in which methane gas was not used, each of the cases (Example) in which methane gas was used showed small XRC half width, significantly small crack density, and small dislocation density. This shows that GaN crystals of high quality with few defects were obtained by Example.

### INDUSTRIAL APPLICABILITY

As described above, according to the present invention, a Group III nitride crystal of high quality with few defects can be produced by vapor phase epitaxy. According to the production method of the present invention, for example, a large Group III nitride crystal of high quality with few defects such as a distortion, dislocation, warping, and the like can be produced. Furthermore, for example, the present invention provides the semiconductor apparatus of the present invention that uses the Group III nitride crystal and the Group III nitride crystal production apparatus that can be used in the production method according to the present invention. For example, by using the Group III nitride crystal produced by the present invention as a substitute for Si in a semiconductor apparatus such as a power device, a high frequency device, or the like generally required to have a large diameter of Si (silicon), the performance can further be improved. The present invention, however, is not limited thereto and is applicable to any other semiconductor apparatuses and other applications besides the semiconductor apparatuses.

### EXPLANATION OF REFERENCE NUMERALS

100, 300, 500 apparatus for use in Group III nitride crystal production method
101 first container
102, 301 second container
103 substrate support
104 Group III element metal placement part
105 oxidizing gas introduction pipe
106 Group III element metal oxidization product gas delivery pipe
107a, 107b, 107d nitrogen-containing gas introduction pipe
107c carrier gas introduction pipe
108 exhaust pipe
109a, 109b first heating unit
200a, 200b second heating unit
201a, 201b, 401a, 401b oxidizing gas or reducing gas
111a, 111b Group III element metal oxidization product gas
202 substrate
203a, 203b, 203c, 203f nitrogen-containing gas
203d exhaust gas
203e, 203g carrier gas
204 Group III nitride crystal (GaN crystal)
205 solid carbon (graphite)
302 Group III element metal introduction pipe
402, 110 Group III element metal

1. A method for producing a Group III nitride crystal, comprising a step of:
causing Group III element-containing gas to react with nitrogen-containing gas to generate a Group III nitride crystal, wherein
in the Group III nitride crystal generation step, the reaction is performed in the presence of a carbon-containing substance.

2. The method according to claim 1, wherein
the carbon-containing substance is at least one selected from the group consisting of elementary carbon, solid elementary carbon, graphite, carbon nanotube, fullerene, a carbon compound, a solid carbon compound, carbon-containing gas, carbon monoxide (CO) gas, and hydrocarbon gas.

3. The method according to claim 1, further comprising a step of:
generating the Group III element-containing gas, wherein
the Group III element-containing gas generation step is a step of causing Group III element oxide to react with reducing gas to generate the Group III element-containing gas.

4. The method according to claim 3, wherein
the reducing gas is at least one selected from the group consisting of H₂ gas, carbon monoxide (CO) gas, hydrocarbon gas, H₂S gas, SO₂ gas, and NH₃ gas.

5. The method according to claim 1, further comprising a step of:
generating the Group III element-containing gas, wherein
the Group III element-containing gas generation step is a step of causing Group III element metal to react with an oxidizing agent to generate the Group III element-containing gas.

6. The method according to claim 5, wherein
the oxidizing agent is oxidizing gas.

7. The method according to claim 6, wherein
the oxidizing gas is at least one selected from the group consisting of H₂O gas, O₂ gas, CO₂ gas, and CO gas.

8. The method according to claim 1, wherein
the nitrogen-containing gas is at least one selected from the group consisting of N₂, NH₃, hydrazine gas, and alkylamine gas.

9. A method for producing a semiconductor apparatus including a Group III nitride crystal, comprising a step of:
producing a Group III nitride crystal by the method according to claim 1, wherein
the Group III nitride crystal is a semiconductor.

10. An apparatus for producing a Group III nitride crystal for use in the method according to claim 1, comprising:
a Group III nitride crystal generation unit configured to perform the Group III nitride crystal generation step.
